(19) United States
(12) Patent Application Publication
(10) Pub. No.: US 2021/0159022 A1
(43) Pub. Date: May 27, 2021

(54) 2D PEROVSKITE TANDEM PHOTOVOLTAIC DEVICES

(71) Applicant: HUNT PEROVSKITE TECHNOLOGIES, L.L.C., Dallas, TX (US)

(72) Inventors: Michael David Irwin, Heath, TX (US); Duyen Hanh Cao, Dallas, TX (US); Kamil Mielczarek, Rowlett, TX (US)

(21) Appl. No.: 16/695,438

(22) Filed: Nov. 26, 2019

(51) Int. Cl. H01G 9/20; H01L 27/30; H01L 51/42; H01L 51/44; H01L 51/00

(52) U.S. Cl. CPC H01G 9/2072; H01G 9/2009; H01L 51/0077; H01L 51/4253; H01L 51/442; H01L 27/302

(57) ABSTRACT

A photovoltaic device includes a first electrode, a first photoactive material layer, one or more interfacial layers, a second photoactive material layer comprising a 2-D perovskite material having the formula (C′)ₐ(C)_{b}MₙX₃ₙ₊₁ and a second electrode. C′ is a bulky organic cation, C is a small organic or inorganic cation, M is a metal, X is a halide, a and b are real numbers, and n is an integer.

### BACKGROUND

Use of photovoltaics (PVs) to generate electrical power from solar energy or radiation may provide many benefits, including, for example, a power source, low or zero emissions, power production independent of the power grid, durable physical structures (no moving parts), stable and reliable systems, modular construction, relatively quick installation, safe manufacture and use, and good public opinion and acceptance of use.

Portions of PVs may be susceptible to halide phase segregation upon sunlight radiation. PVs may function better if protected from moisture that leads to degradation and lack of performance.

The features and advantages of the present disclosure will be readily apparent to those skilled in the art. While numerous changes may be made by those skilled in the art, such changes are within the spirit of the invention.

### SUMMARY

According to some embodiments, a photovoltaic device includes a first electrode, a first photoactive material layer, one or more interfacial layers, a second photoactive material layer comprising a 2-D perovskite material having the formula (C′)ₐ(C)_{b}MₙX₃ₙ₊₁ and a second electrode. C′ is a bulky organic cation, C is a small organic or inorganic cation, M is a metal, X is a halide, a and b are real numbers, and n is an integer.

According to some embodiments, a photovoltaic device includes a first electrode, an interfacial layer, a second electrode, a first photoactive material layer selected from the group consisting of perovskite, silicon, CdTe, CIGS, GaAs, InP, and Ge, a second photoactive material layer comprising a 2-D perovskite material having the formula (C′)ₐ(C)_{b}MₙX₃ₙ₊₁. C′ is a bulky organic cation, C is a small organic or inorganic cation, M is a metal, X is a halide or pseudohalide, a and b are real numbers, and n is an integer. The first photoactive material is positioned between the first electrode and the interfacial layer. The second photoactive material layer is positioned between the interfacial layer and the second electrode.

### BRIEF DESCRIPTION OF THE DRAWINGS

FIG. 1 is a stylized diagram of a 2-terminal tandem photovoltaic cell, according to some embodiments of the present disclosure.

FIG. 2 is a stylized diagram of a 3-terminal tandem photovoltaic cell, according to some embodiments of the present disclosure.

FIG. 3 is a stylized diagram of a 4-terminal tandem photovoltaic cell, according to some embodiments of the present disclosure.

FIG. 4 is an illustration of photoluminescence spectra of 2D halide perovskites having various thicknesses of inorganic halide sublattices.

FIG. 5 provides a stylized illustration of thicknesses of inorganic metal halide sublattices of perovskite materials according to some embodiments of the present disclosure.

FIGS. 6-18 provide illustrations of the structures of various bulky organic molecules that form 2D perovskites.

FIG. 19 provides a stylized diagram of example recombination layers, according to some embodiments of the present disclosure.

FIG. 20 provides a stylized diagram of a 2D perovskite material/silicon tandem photovoltaic cell, according to some embodiments of the present disclosure.

FIG. 21 is a stylized diagram of a photovoltaic cell with three photoactive layers, according to some embodiments of the present disclosure.

### DETAILED DESCRIPTION OF PREFERRED EMBODIMENTS

Improvements in various aspects of PV technologies compatible with organic, non-organic, and/or hybrid PVs promise to further lower the cost of both organic PVs and other PVs. For example, some solar cells, such as perovskite PV solar cells, may take advantage of novel cost-effective and high-stability alternative components, such as nickel oxide interfacial layers. In addition, various kinds of solar cells may advantageously include chemical additives and other materials that may, among other advantages, be more cost-effective and durable than conventional options currently in existence.

The present disclosure relates generally to compositions of matter of use in creating electrical energy from solar radiation. More specifically, this disclosure relates to photoactive and other compositions of matter.

Some or all of materials in accordance with some embodiments of the present disclosure may also advantageously be used in any organic or other electronic device, with some examples including, but not limited to: batteries, field-effect transistors (FETs), light-emitting diodes (LEDs), non-linear optical devices, memristors, capacitors, rectifiers, and/or rectifying antennas.

Metal halides in perovskites present a versatile class of solution-processable semiconductors with excellent optoelectronic properties. The use of metal halides in tandem solar cells has been demonstrated in literature in which c-Si or three-dimensional (3D) perovskites serve as the bottom-cell and 3D perovskites serve as the top-cell. Perovskite-containing tandem solar cells reported thus far employ 3D lead iodide mixed with bromide to achieve the desired top-cell optical band gap of around 1.7 eV. However, mixed halide anions have been shown to be intrinsically unstable such that upon continuous irradiation they segregate into iodide- and bromide-phases which detrimentally affects the light harvesting efficiency of the top cell. Thus, there is a need for an improved solution.

This disclosure provides a tandem solar cell device architecture where a cell made from two-dimensional (2D) metal halide perovskites, is monolithically stacked on top of the bottom-cell, made from, for example c-Si (in a 2- or 3-terminal design) or mechanically stacked on top of the bottom-cell (in a 4-terminal design).

In some embodiments, the present disclosure may provide PV and other similar devices (e.g., batteries, hybrid PV batteries, multi junction PVs, FETs, LEDs, x-ray detectors, gamma ray detectors, photodiodes, CCDs, etc.). Such devices may in some embodiments include improved active material, interfacial layers (IFLs), and/or one or more perovskite materials. A perovskite material may be incorporated into various of one or more aspects of a PV or other device. A 2D perovskite material according to some embodiments may be of the general formula (C′)ₐ(C)_{b}MₙX₃ₙ₊₁, wherein C′ is a bulky organic cation, C is a smaller organic or inorganic cation, M is a divalent metal, X is a halide or pseudohalide, a and b are real numbers, and n is an integer. In other embodiments, M may be a combination of monovalent and trivalent metals and may be written in the form M′M″ where M′ is a monovalent metal and M″ is a trivalent metal. In such embodiments, the ratio of monovalent metal to trivalent metal may range from 1:99 to 50:50, and in particular embodiments, may be 1:99, 25:75; or 50:50.

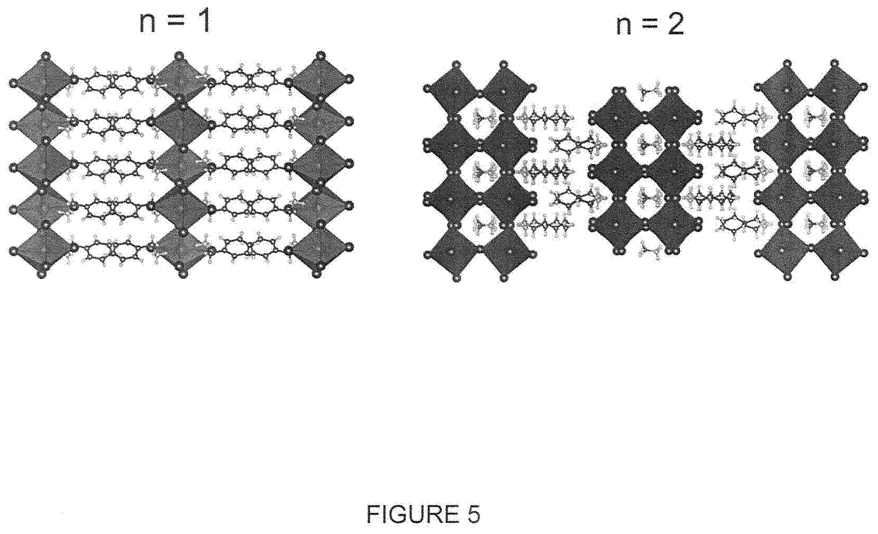

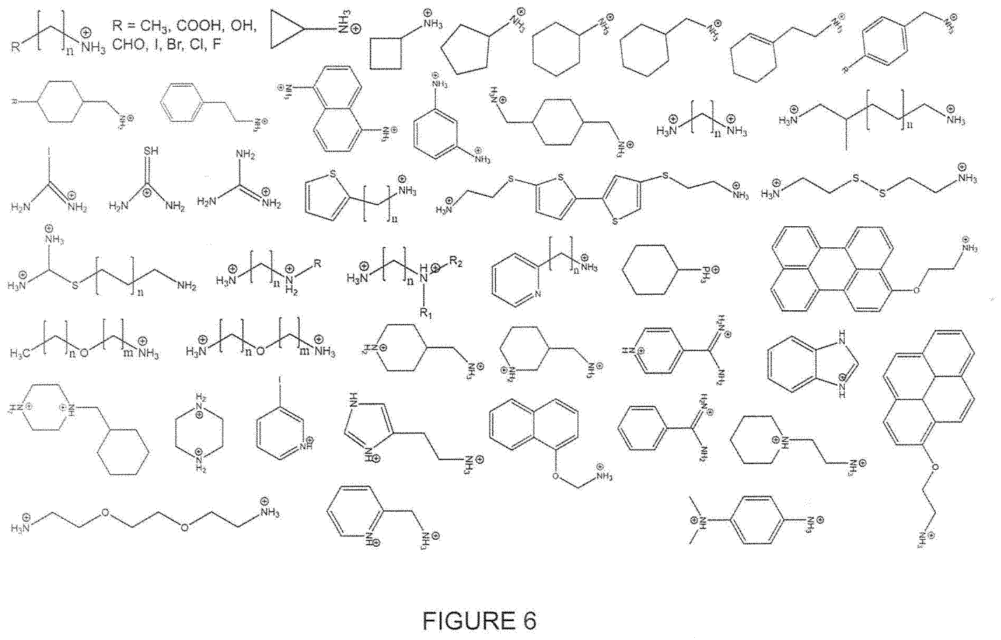

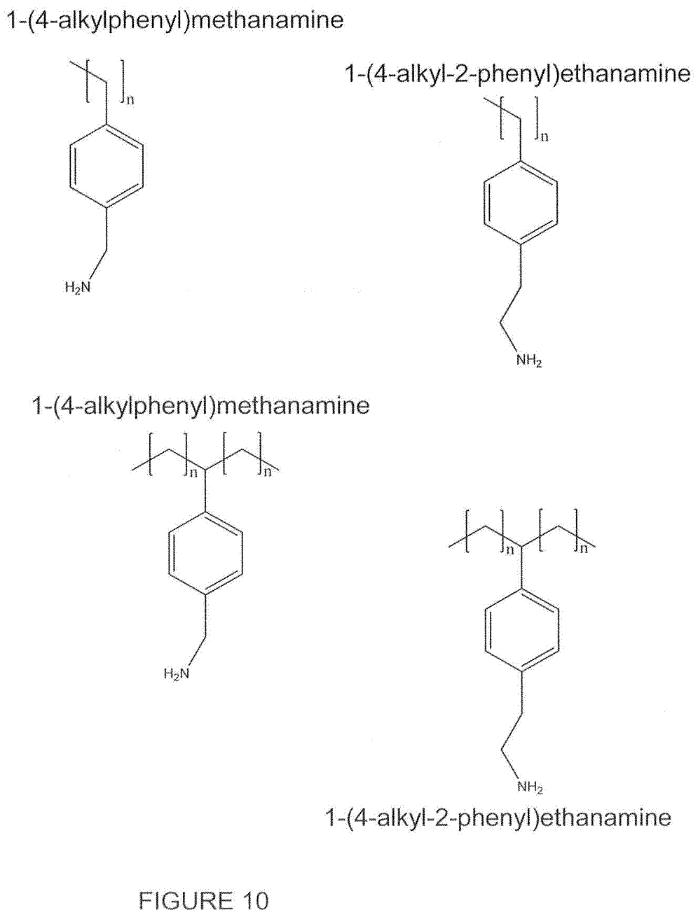

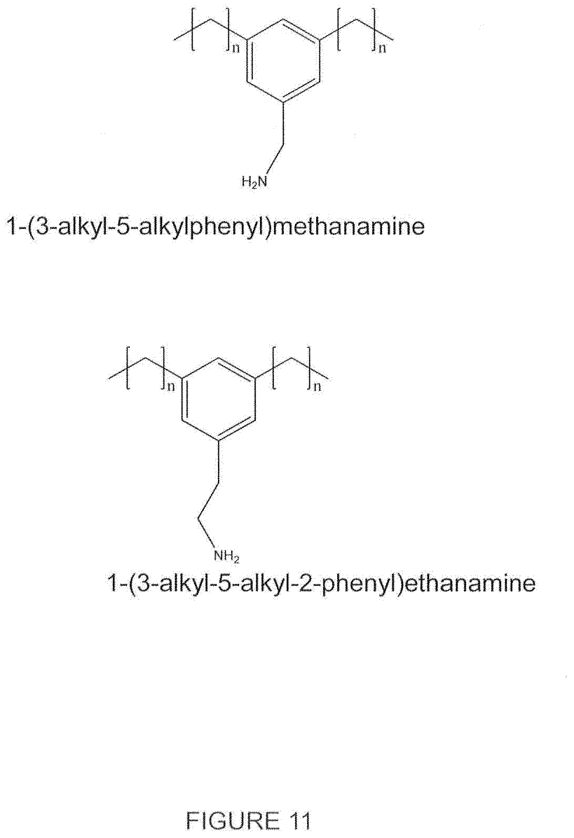

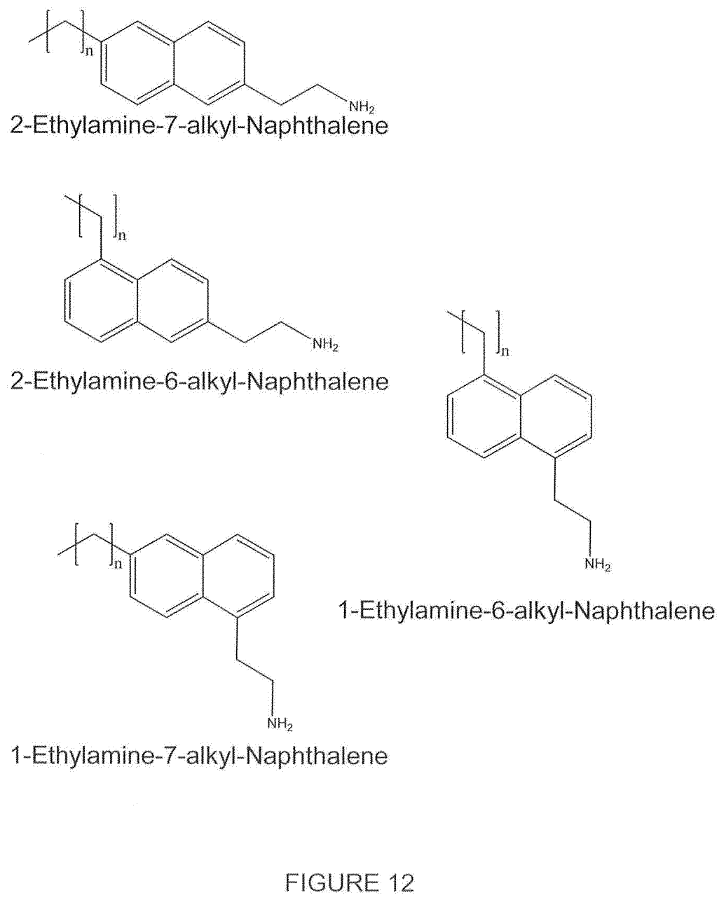

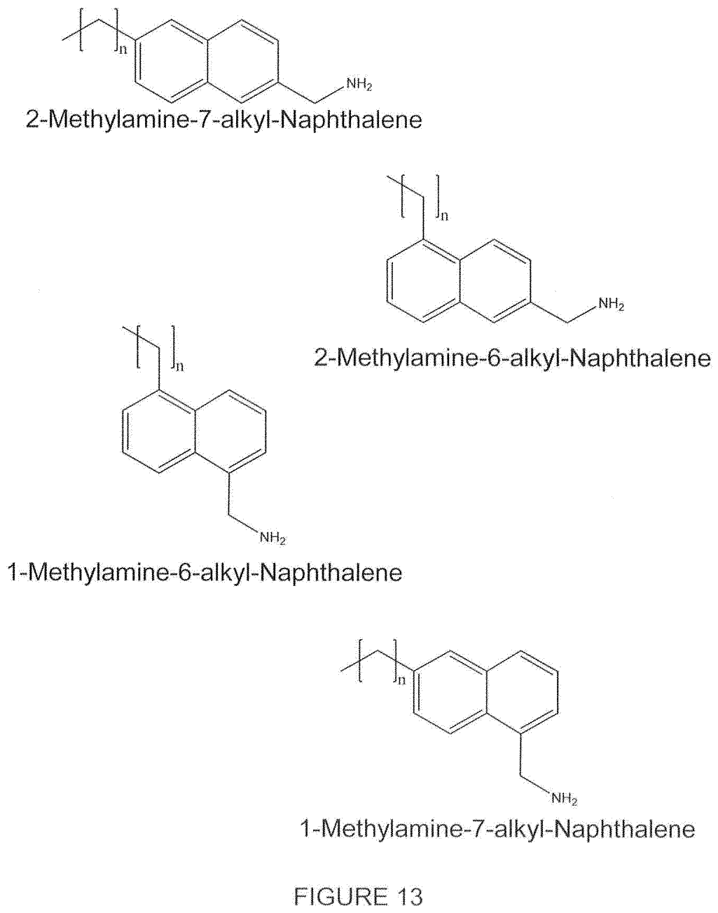

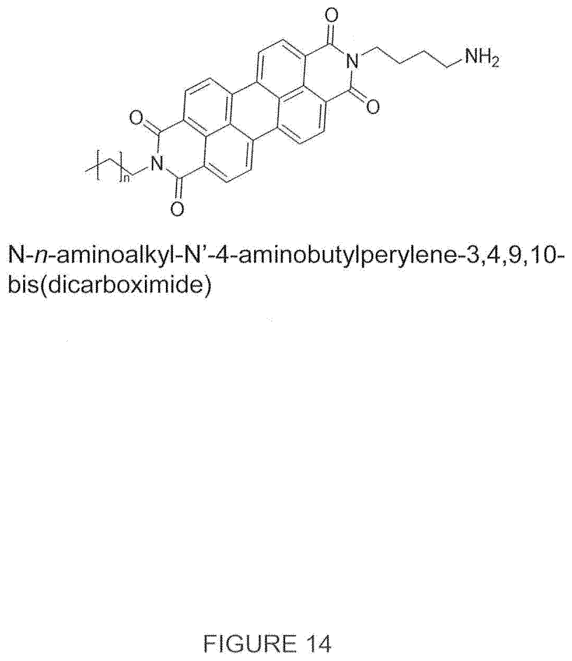

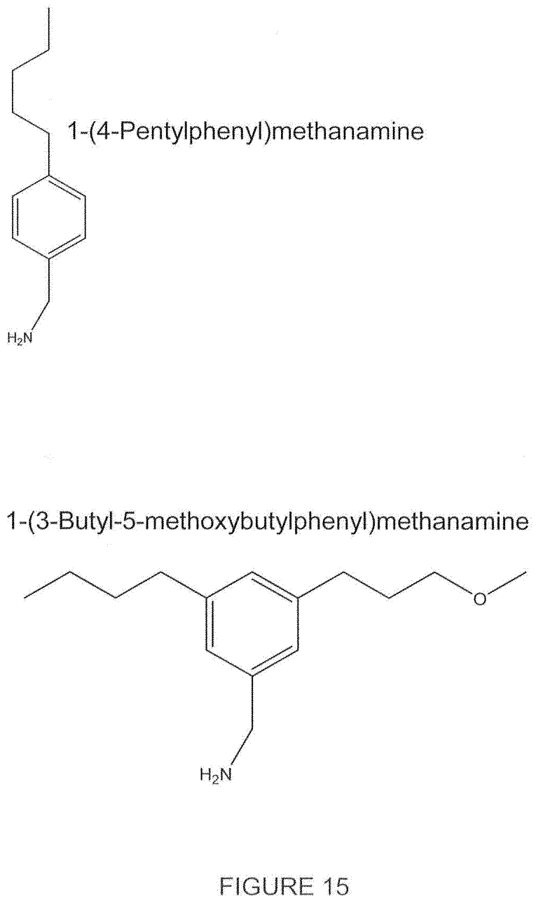

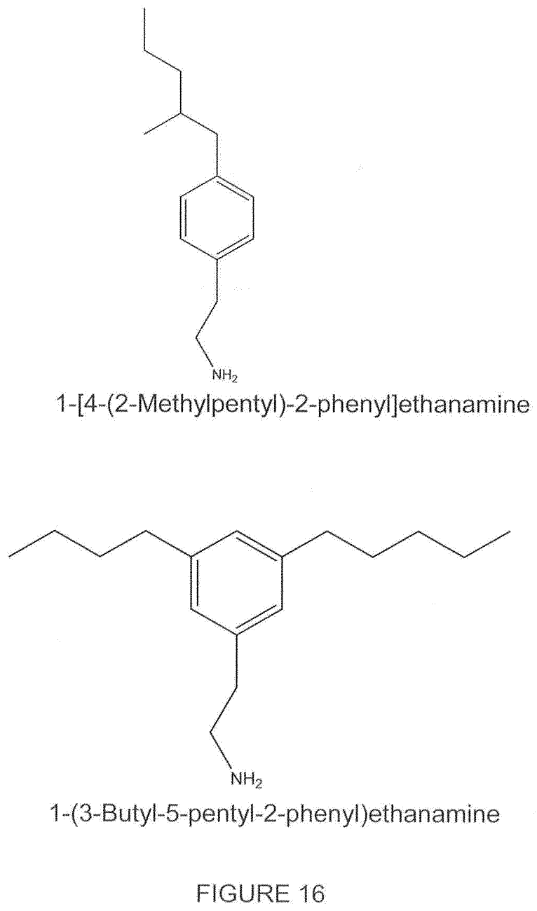

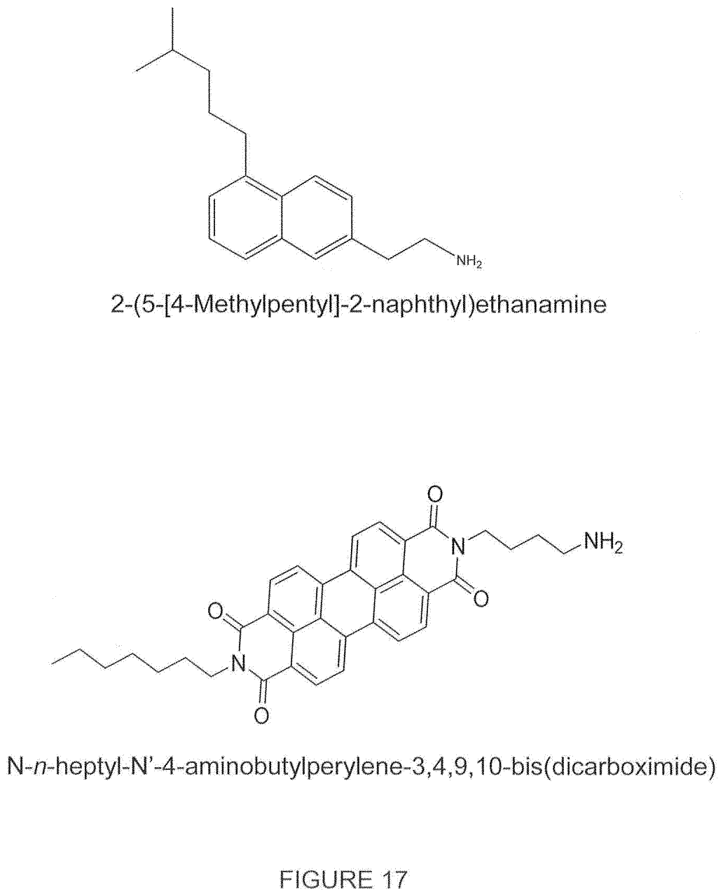

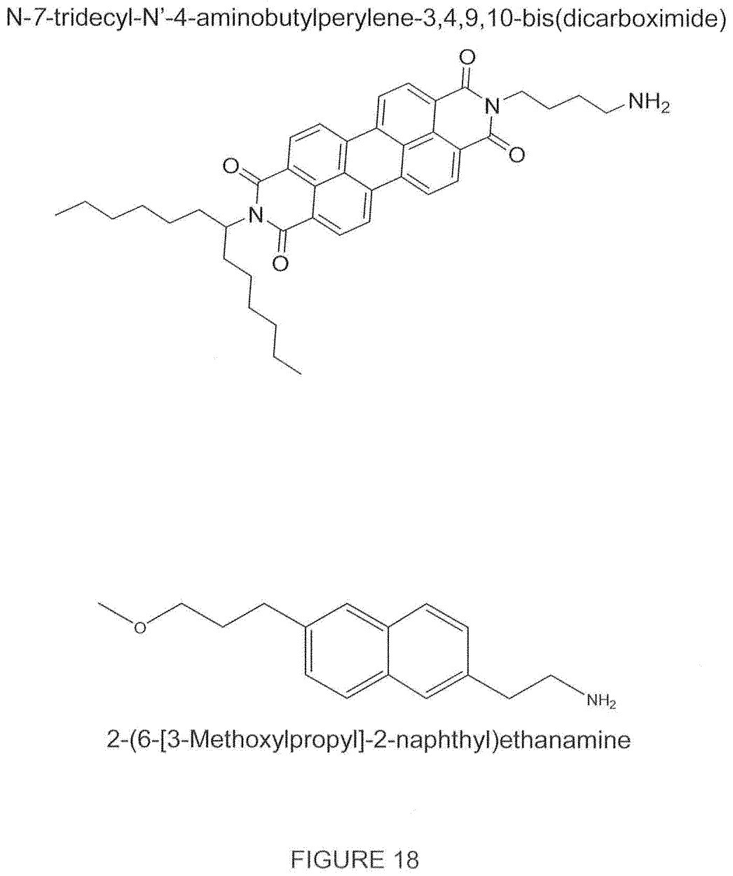

As illustrated in FIG. 5, the n value indicates the thickness of an inorganic metal halide sublattice comprising at least one of Pb, I, N, C, and H. The structures of various bulky organic molecules (C′) are illustrated in FIGS. 6-18.

In general, tandem photovoltaic cells, “tandem PVs,” include two photoactive layers. One photoactive layer generally is a material that has a wider band gap than the material that makes up the other photoactive layer. The wider band gap photoactive material, such as a 2D perovskite of the present disclosure, is situated closest to the sun-facing side of the PV cell and collects short wave length radiation more efficiently than the narrower band gap photoactive material. The narrower band gap material, such as silicon, CdTe, or non-2D perovskite, is more efficient at absorbing longer wavelength light that is not absorbed by the wider bandgap photoactive material. This disclosure identifies the potential choices for C′, C, M, X, and the n value to achieve an optical band gap of 1.70-1.90 eV for the top cell, in some embodiments, as well as improving the long-term stability of, for example, Si/perovskite tandem solar cells. The bandgap may be tailored for the properties of the bottom cells, in cases such as CdTe/perovskite, CIGS/perovskite, GaAs/perovskite, InP/perovskite, Ge/perovskite, perovskite/perovskite, PbS/perovskite, amongst others. In certain embodiments, n is a value between 1 and 10, and in particular embodiments between 3 and 4, X is iodide, M is lead, C is cesium, methylammonium (MA) or formamidinium (FA), and C′ is one of benzylammonium, phenylethylammonium, n-butylammonium, iminomethanediammonium, and a cation of 4-(aminomethyl)piperidine.

Two-dimensional lead iodide perovskite compounds, like the compounds described in some embodiments of this disclosure, substantially contain a single type of anion (e.g. only a single species of halide or pseudohalide such as only thiocyanate, only iodide, only bromide, or only chloride) with no more than trace amounts of other species. Thus, they will not undergo halide phase segregation upon sunlight irradiation, unlike the mixture of iodide and bromide currently used in the state-of-the-art Si/perovskite and perovskite/perovskite tandem solar cells. Thus, this disclosure contemplates systems consisting substantially of of iodide, bromide or chloride.

Photovoltaic Cells and Other Electronic Devices

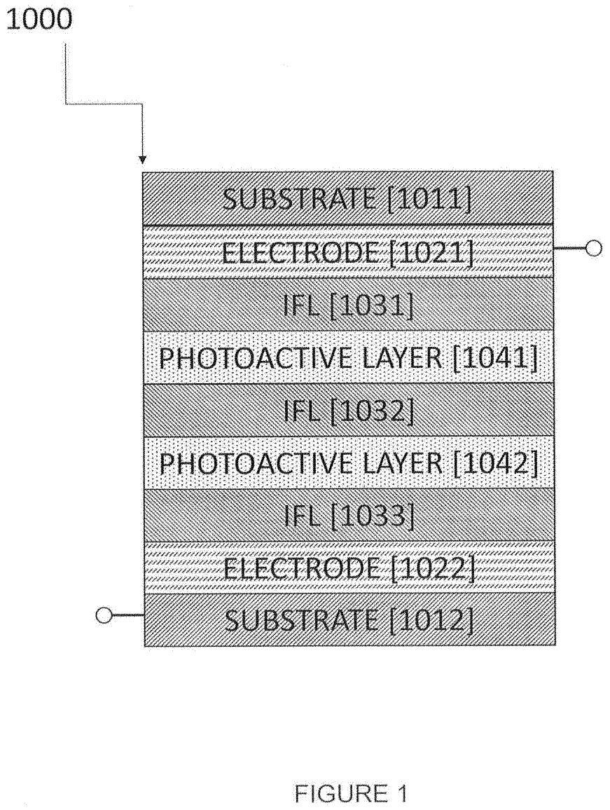

Some PV embodiments may be described by reference to the illustrative depictions of solar cells as shown in FIG. 1-3. An example PV architecture, according to some embodiments, may be generally of the form substrate-electrode-IFL-active layer-IFL-electrode-substrate. electrode-substrate-IFL-substrate-electrode. The active layer of some embodiments may be photoactive, and/or it may include photoactive material. Other layers and materials may be utilized in the cell as is known in the art. Furthermore, it should be noted that the use of the term “active layer” is in no way meant to restrict or otherwise define, explicitly or implicitly, the properties of any other layer. For instance, in some embodiments, the IFL may also be active insofar as they may be semiconducting.

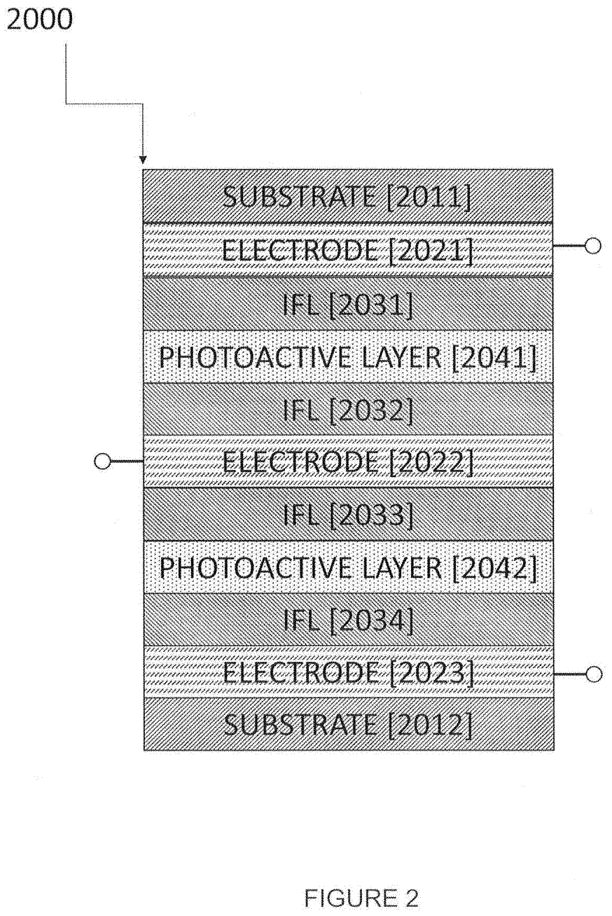

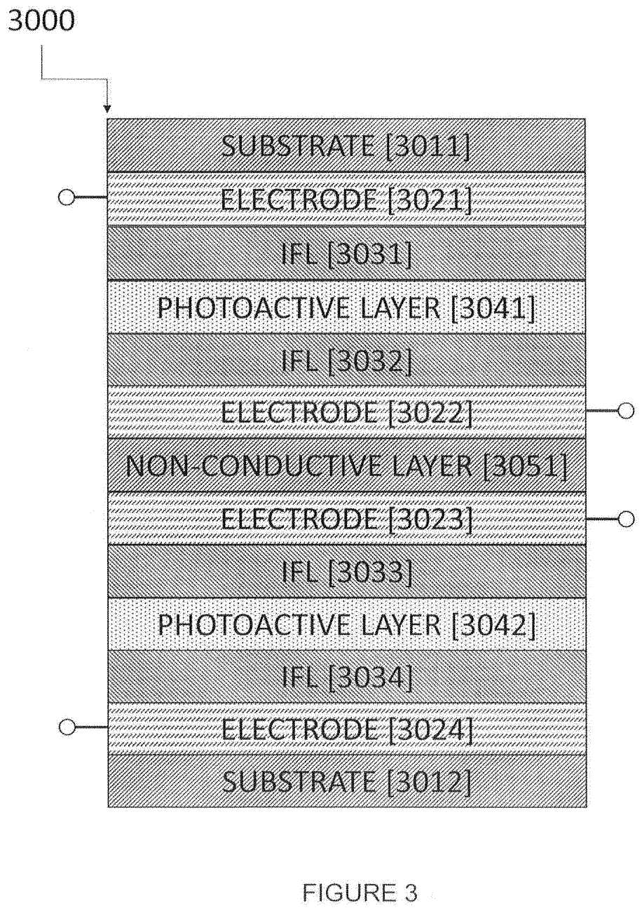

Referring to FIG. 1, a stylized generic PV cell 1000 is depicted, illustrating the highly interfacial nature of some layers within the PV. The PV 1000 represents a generic architecture applicable to several PV devices, such as perovskite material PV embodiments. FIG. 1 will be discussed in detail below. With references to FIGS. 2 and 3, it should be understood that the characteristics of electrodes 2021, 2022, 2023, 3021, 3022, 3023, and 3024 may be consistent with those of electrodes 1010 and 1050. Additionally, the characteristics of IFLs 2031, 2032, 2033, 2034, 3031, 3032, 3033, and 3034 may be consistent with those of IFL 1031, 1032, and 1033. The characteristics of substrates 2011 and 3011 may be consistent with those of 1011 while the characteristic of substrates 2012 and 3012 are consistent with those of substrate 1012. Further, although various components of the devices 1000, 2000, and 3000 are illustrated as discrete layers comprising contiguous material, it should be understood that FIGS. 1, 2, and 3 are stylized diagrams; thus, embodiments in accordance with FIGS. 1, 2, and 3 may include such discrete layers, and/or substantially intermixed, non-contiguous layers, consistent with the usage of “layers” discussed herein.

Additionally, the architectures exhibited in FIGS. 1, 2, 3, 20, and 21 may be adapted so as to provide the BHJs, batteries, FETs, hybrid PV batteries, serial multi-cell PVs, parallel multi-cell PVs and other similar devices of other embodiments of the present disclosure, in accordance with any suitable means (including both those expressly discussed elsewhere herein, and other suitable means, which will be apparent to those skilled in the art with the benefit of this disclosure).

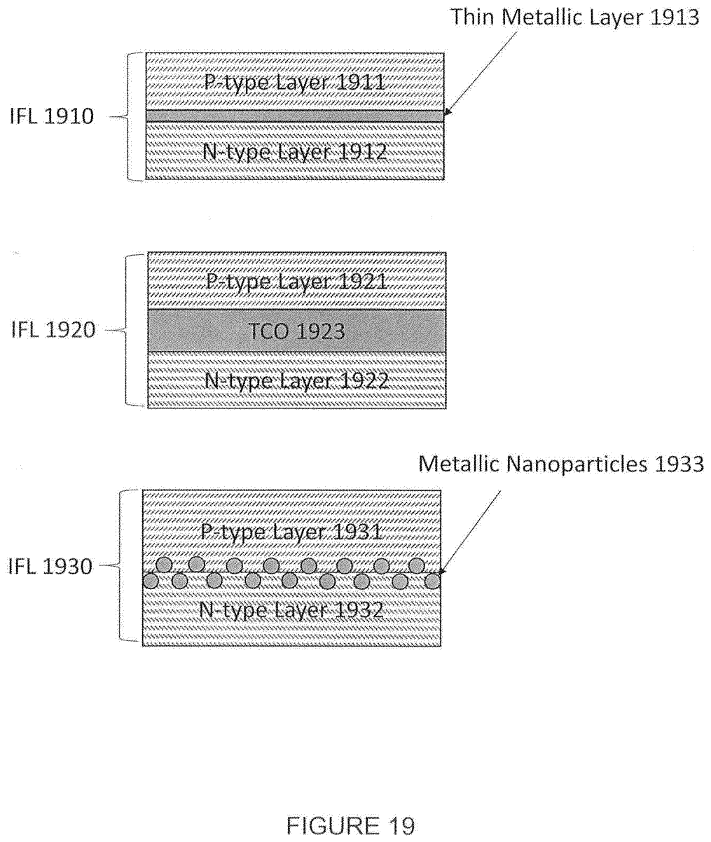

The PV cell 1000 includes two electrically conductive electrode layers, a first electrode layer 1021 and a second electrode layer 1022. Electrode layers 1021 and 1022 may be transparent conductors such as tin-doped indium oxide (ITO) or any other material as described herein. In other embodiments, electrode layers 1021 and 1022 may be a metal, such as aluminum, or other conducive material such as carbon. PV cell 1000 also includes interfacial layers (IFL) 1031, 1032, and 1033. IFLs 1031, 1032, and 1033 may assist in charge recombination. In some embodiments, each IFL layer may be a multi-layer IFL, which is discussed in greater detail herein. In particular embodiments, IFL 1032 may be a multi-layer recombination layer IFL, such as one of the IFLs illustrated by FIG. 19. An IFL may be intrinsic, ambipolar, p-type, or n-type semiconducting materials or may be a dielectric material.

PV cells 1000, 2000, and 3000 of FIGS. 1, 2, and 3 also include photoactive layers. In general, photoactive materials (e.g., photoactive layers 1041 or 1042 of FIG. 1, photoactive layers 2041 or 2042 of FIG. 2, or photoactive layers 3041 or 3042 of FIG. 3) may include any photoactive compound, such as any one or more of perovskite (for example, FAPbI₃, FASnI₃, MASnI₃, or CsSnI₃), silicon (for example, polycrystalline silicon, single-crystalline silicon, or amorphous silicon), cadmium telluride, cadmium sulfide, cadmium selenide, copper indium gallium selenide, copper indium selenide, copper zinc tin sulfide, gallium arsenide, germanium, germanium indium phosphide, indium phosphide, lead sulfide, one or more semiconducting polymers (e.g., polythiophenes (e.g., poly(3-hexylthiophene) and derivatives thereof, or P3HT); carbazole-based copolymers such as polyheptadecanylcarbazole, dithienylbenzothiadiazole and derivatives thereof (e.g., PCDTBT); other copolymers such as polycyclopentadithiophene benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); polyphenylene vinylenes and derivatives thereof (e.g., MDMO-PPV, MEH-PPV), and combinations thereof. Any one or more of these photoactive layers may include one or more perovskite materials.

In certain embodiments, photoactive material may instead or in addition comprise a dye (e.g., N719, N3, other ruthenium-based dyes). In some embodiments, a dye (of whatever composition) may be coated onto another layer (e.g., a mesoporous layer and/or an interfacial layer). In some embodiments, photoactive material may include one or more perovskite materials. Perovskite-material-containing photoactive substance may be of a solid form, or in some embodiments it may take the form of a dye that includes a suspension or solution comprising perovskite material. Such a solution or suspension may be coated onto other device components in a manner similar to other dyes. In some embodiments, solid perovskite-containing material may be deposited by any suitable means (e.g., vapor deposition, solution deposition, direct placement of solid material). Devices according to various embodiments may include one, two, three, or more photoactive compounds (e.g., one, two, three, or more perovskite materials, dyes, or combinations thereof). In certain embodiments including multiple dyes or other photoactive materials, each of the two or more dyes or other photoactive materials may be separated by one or more interfacial layers. In some embodiments, multiple dyes and/or photoactive compounds may be at least in part intermixed.

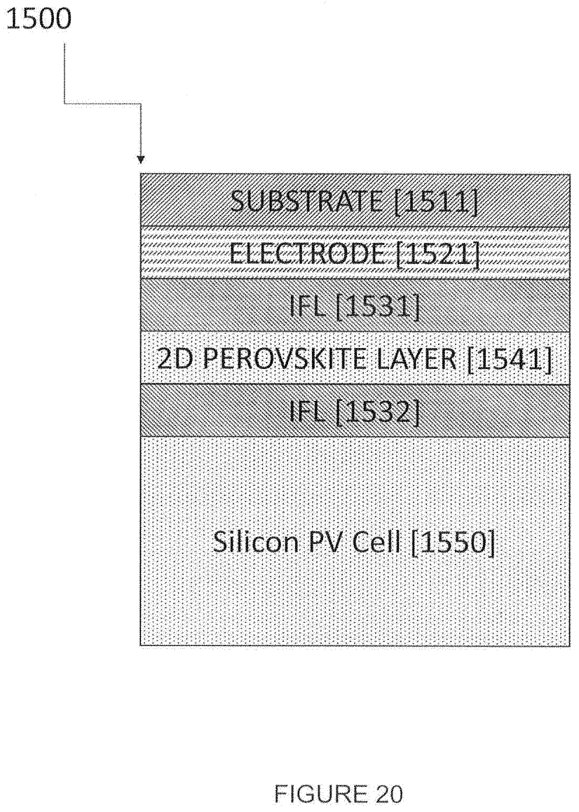

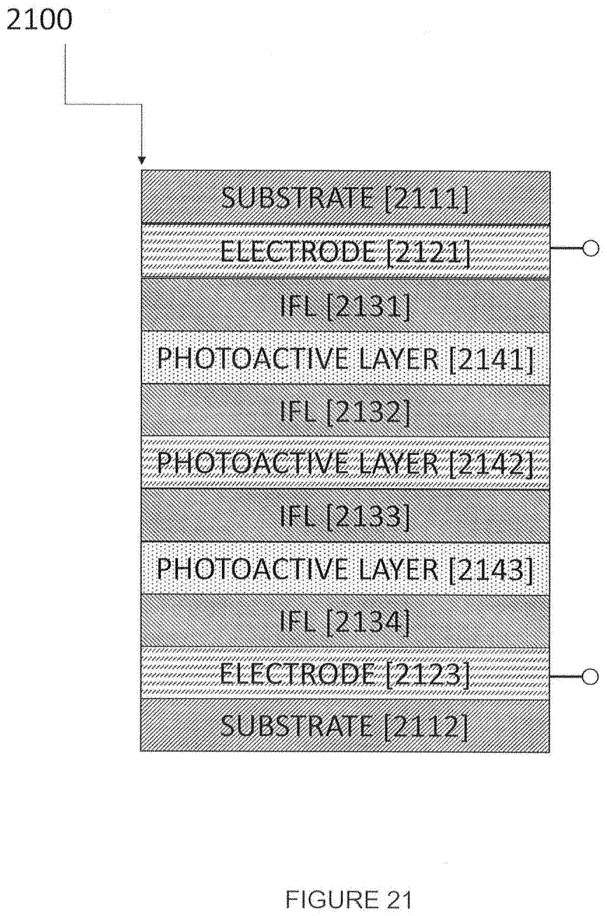

PV cell 1000 may be attached to electrical leads by electrodes 1021 and 1022, which may connect PV cell 1000 to a discharge unit, such as a battery, motor, capacitor, electric grid, or any other electrical load. An electrode may constitute any conductive material, and at least one electrode should be transparent or translucent to EM radiation, and/or be arranged in a manner that allows EM radiation to contact at least a portion of the active layers of device 1000. Suitable electrode materials may include any one or more of: indium tin oxide or tin-doped indium oxide (ITO); fluorine-doped tin oxide (FTO); cadmium oxide (CdO); zinc indium tin oxide (ZITO); aluminum zinc oxide (AZO); aluminum (Al); gold (Au); silver (Ag); calcium (Ca); chromium (Cr); magnesium (Mg); titanium (Ti); steel; carbon (and allotropes thereof); doped carbon (e.g., nitrogen-doped); nanoparticles in core-shell configurations (e.g., silicon-carbon core-shell structure); and combinations thereof. In some embodiments, an electrode may be a grid, web, or mesh of any of the forgoing materials. Grid, web, or mesh electrodes may provide for transparency of the electrodes when constructed of materials that would not otherwise be transparent. For example, metal electrodes of a recombination IFL, such as electrode 1913 of FIG. 19, may be implemented as a grid, web, or mesh electrode. Such electrodes may be incorporated into recombination layer IFLs such as IFL 1032 of FIG. 1, IFL 1532 of FIG. 20, and IFLs 2132 and 2133 of FIG. 21. Likewise, grid, web, or mesh electrodes may be incorporated as electrodes residing “in” three, four, or more terminal PV devices, such as electrode 2022 of FIG. 2, and electrodes 3022 and 3023 of FIG. 3. FIG. 2 illustrates a 3-terminal PV cell 2000. PV cell 2000 may be attached to electrical leads by electrode 2021, an electrode 2022 embedded within IFLs 2032 and 2033, and electrode 2023. In some embodiments, electrode layers 2021 and 2023 may be cathodes and electrode layer 2022 may be an anode. In other embodiments, electrode layers 2021 and 2023 may be anodes and electrode layer 2022 may be a cathode. As with PV cell 1000 illustrated in FIG. 1, IFLs 2031, 2032, 2033, and 2034 may be single or multi-layer IFLs and may be intrinsic, ambipolar, p-type, or n-type semiconducting materials or may be a dielectric material. In embodiments in which electrode layer 2022 is a cathode, IFLs 2032 and 2033 may be electron transporting layers (n-type layers). In embodiments in which electrode layer 2022 is an anode, IFLs 2032 and 2033 may be hole transporting layers (p-type). In some embodiments, one or more of IFLs 2031, 2032, 2033, or 2034 may be omitted from PV cell 2000.

FIG. 3 illustrates a 4-terminal PV cell 3000. PV cell 3000 may be attached to electrical leads by electrode layers 3021, 3022, 3023, and 3024. In some embodiments, electrode layer 3021 may be an anode and electrode layer 3022 may be a cathode, and electrode layer 3024 may be an anode and electrode layer 3023 may be a cathode. In other embodiments, electrode layer 3021 may be an anode and electrode layer 3022 may be a cathode, and electrode layer 3024 may be a cathode and electrode layer 3023 may be an anode. In other embodiments, electrode layer 3021 may be a cathode and electrode layer 3022 may be anode, and electrode layer 3024 may be a cathode and electrode layer 3023 may be an anode. In other embodiments, electrode layer 3021 may be a cathode and electrode layer 3022 may be anode, and electrode layer 3024 may be an anode and electrode layer 3023 may be a cathode. A 4-terminal design tandem solar cell device may, in some embodiments, include two devices made up of monolithically stacked layers. The two devices may be joined using a layer of adhesive, epoxy, glass, sapphire, laminate, polymer, plastic, or any combination thereof. For example, with reference to FIG. 3, a first device may include substrate 3011, electrode layer 3021, ILF 3031, photoactive layer 3041, IFL 3032, and electrode layer 3022, and a second device may include substrate 3012, electrode layer 3024, ILF 3034, photoactive layer 3042, IFL 3033, and electrode layer 3023. These devices may be joined by transparent, non-conductive layer 3051, which may be an adhesive, epoxy, glass, sapphire, laminate, polymer, plastic, or combination thereof.

As with PV cell 1000 and PV cell 2000 illustrated in FIGS. 1 and 2, IFLs 3031, 3032, 3033, and 2034 may be single or multi-layer IFLs and may be intrinsic, ambipolar, p-type, or n-type semiconducting materials or may be a dielectric material. In embodiments in which electrode layer 3022 and/or electrode layer 3023 is a cathode, IFL 2032 and/or IFL 2033 may be electron transporting layers (n-type layers). In embodiments in which electrode layer 3022 and/or electrode layer 3023 is an anode, IFL 3032 and/or IFL 3033 may be hole transporting layers (p-type). In some embodiments, one or more of IFLs 2031, 2032, 2033, or 2034 may be omitted from PV cell 3000. Non-conductive layer 3051, may be any transparent material that does not conduct electricity between electrode layer 3022 and electrode layer 3023. For example, non-conductive layer 3051 may be glass, sapphire, quartz, silicon carbide, or a transparent polymer such as polyethylene terephthalate, polyethylene naphthalate, polycarbonate or poly(methyl methacrylate) (PMMA).

In certain embodiments, at least one IFL, electrode, substrate, and photoactive layer must be transparent to light having a wavelength greater than 500 nanometers to allow light to reach the second photoactive layer.

Additionally, while the discussion in this disclosure is primarily directed to tandem PV cells having two photoactive layers, the general principles described herein may apply to a PV cell with more than two photoactive layers. For example, FIG. 21 illustrates a PV cell with three photoactive layers 2141, 2142, and 2143. In accordance with the disclosure contained herein, in an embodiment in which photoactive layer 2141 is disposed closest to the light incident side of PV 2100, photoactive layer 2141 would have a larger band gap than photoactive layer 2142, which in turn would have a larger band gap than photoactive layer 2143. In particular embodiments, photoactive layer 2141 includes a 2D perovskite material, photoactive layer 2142 includes a perovskite material, and photoactive layer 2143 includes lead sulfide (PbS). In another embodiment, photoactive layer 2141 includes a 2D perovskite material, photoactive layer 2142 includes gallium arsenide (GaAs), and photoactive layer 2143 includes germanium (Ge). In yet another embodiment, photoactive layer 2141 includes a 2D perovskite material, photoactive layer 2142 includes a perovskite material, and photoactive layer 2143 includes silicon. In yet another embodiment, photoactive layer 2141 includes a 2D perovskite material, photoactive layer 2142 includes a 2D perovskite material with a narrower bandgap than the 2D perovskite material of photoactive layer 2141, and photoactive layer 2143 includes silicon.

Any suitable substrate, electrode, IFL, or photoactive material described herein may be implemented as the respective layers of PV device 2100.

The PV cell 1000 also includes a first photoactive layer 1041. First photoactive layer 1041 may include a first photoactive material. In certain embodiments, the first photoactive material may be a 2-D perovskite material having the formula (C′)ₐ(C)_{b}MₙX₃ₙ₊₁, wherein C′ is a bulky organic cation, C is a small organic or inorganic cation, M is a divalent metal, X is a halide or pseudohalide, and a and b are real numbers, and n is an integer. In other embodiments, M may be a combination of monovalent and trivalent metals and may be written in the form M′M″ where M′ is a monovalent metal and M″ is a trivalent metal. In such embodiments, the ratio of monovalent metal to trivalent metal may range from 1:99 to 50:50, and in particular embodiments, may be 1:99, 25:75; or 50:50. As illustrated in FIG. 5, the n value indicates the thickness of an inorganic metal halide sublattice including at least one of Pb, I, N, C, and H. FIG. 6 to FIG. 18 provide chemical structures of organic compounds that may be included in the perovskite material as C′ or C cations. In some embodiments, C′ comprises a cation with a 2⁺ charge including one or more of an imidazolium cation, an aromatic, cyclic organic cation of the general formula [CRNRCRNRCR]²⁺ where the R groups may be the same or different groups, diammonium butane, a Group 1 metal, a Group 2 metal, and/or other cations or cation-like compounds. In certain embodiments, C′ is benzylammonium and C is cesium, methylammonium or formamidinium. In other embodiments, C′ is phenylethylammonium and C is cesium, methylammonium or formamidinium. In certain embodiments, C′ is n-butylammonium and C is cesium, methylammonium or formamidinium. In other embodiments, C′ is iminomethanediammonium and C is cesium, methylammonium or formamidinium. In certain embodiments, C′ is a cation of 4-(aminomethyl)piperidine and C is cesium, methylammonium or formamidinium. In other embodiments, C′ is alkylammonium and C is cesium, methylammonium or formamidinium. In certain embodiments, C′ is alkyldiammonium and C is cesium, methylammonium or formamidinium. In other embodiments, C′ is guanidinium and C is cesium, methylammonium or formamidinium. In certain embodiments, C′ is thienylalkylammonium and C is cesium, methylammonium or formamidinium.

Examples of other “bulky organic” organic cations that may function as C′, include, but are not limited to, ethylammonium, propylammonium, n-butylammonium; perylene n-butylamine-imide; butane-1,4-diammonium; 1-pentylammonium; 1-hexylammonium; poly(vinylammonium); phenylethylammonium; 3-phenyl-1-propylammonium; 4-phenyl-1-butylammonium; 1,3-dimethylbutylammonium; 3,3-dimethylbutylammonium; 1-heptylammonium; 1-octylammonium; 1-nonylammonium; 1-decylammonium; and 1-eicosanyl ammonium. Additionally, bulky organic cations with a tail that contains one or more heteroatoms in addition to the cationic species, the heteroatom may coordinate with, bind to, or integrate with the perovskite material crystal lattice. A heteroatom may be any atom in the tail that is not hydrogen or carbon, including boron, nitrogen, sulfur, oxygen, or phosphorous.

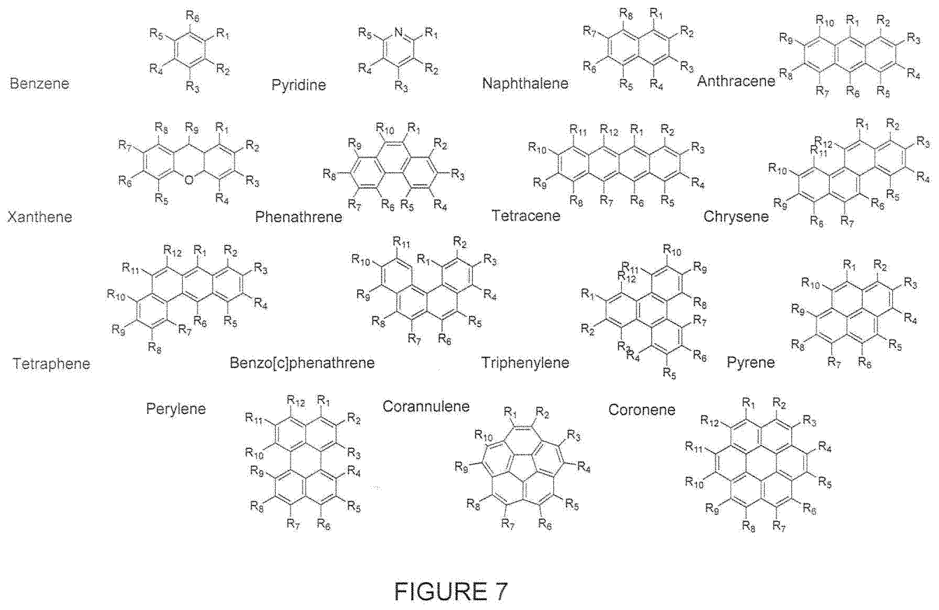

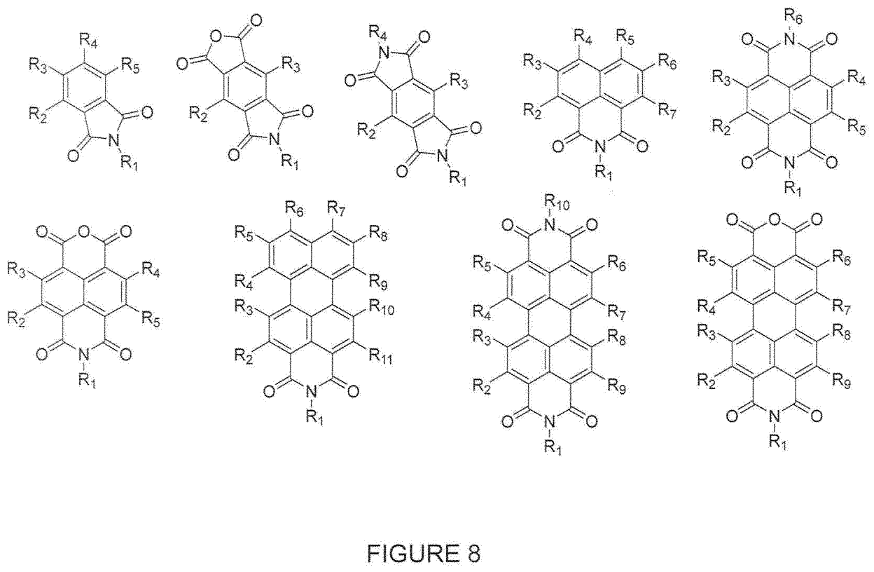

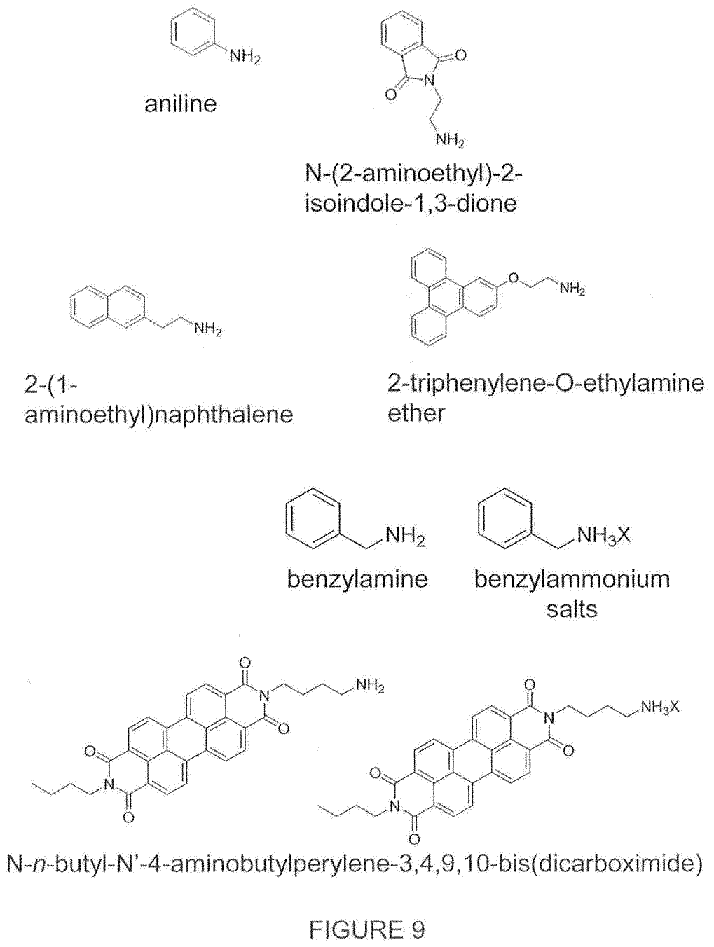

Other examples of bulky organic cations may include the following molecules functionalized with an ammonium group, phosphonium group, or other cationic group that may integrate into a surface C-site of a perovskite material: benzene, pyridine, naphthalene, anthracene, xanthene, phenanthrene, tetracene chrysene, tetraphene, benzo[c]phenathrene, triphenylene, pyrene, perylene, corannulene, coronene, substituted dicarboxylic imides, aniline, N-(2-aminoethyl)-2-isoindole-1,3-dione, 2-(1-aminoethyl)naphthalene, 2-triphenylene-O-ethyl amine ether, benzylamine, benzylammonium salts, N-n-butyl-N′-4-aminobutylperylene-3,4,9,10-bis(dicarboximide), 1-(4-alkylphenyl)methanamine, 1-(4-alkyl-2-phenyl)ethanamine, 1-(4-alkylphenyl)methanamine, 1-(3-alkyl-5-alkylphenyl)methanamine, 1-(3-alkyl-5-alkyl-2-phenyl)ethanamine, 1-(4-alkyl-2-phenyl)ethanamine, 2-Ethylamine-7-alkyl-Naphthalene, 2-Ethylamine-6-alkyl-Naphthalene, 1-Ethylamine-7-alkyl-Naphthalene, 1-Ethylamine-6-alkyl-Naphthalene, 2-Methylamine-7-alkyl-Naphthalene, 2-Methylamine-6-alkyl-Naphthalene, 1-Methylamine-7-alkyl-Naphthalene, 1-Methylamine-6-alkyl-Naphthalene, N-n-aminoalkyl-N′-4-aminobutylperylene-3,4,9,10-bis(dicarboximide), 1-(3-Butyl-5-methoxybutylphenyl)methanamine, 1-(4-Pentylphenyl)methanamine, 1-[4-(2-Methylpentyl)-2-phenyl]ethanamine, 1-(3-Butyl-5-pentyl-2-phenyl)ethanamine, 2-(5-[4-Methylpentyl]-2-naphthyl)ethanamine, N-7-tridecyl-N′-4-aminobutylperylene-3,4,9,10-bis(dicarboximide), N-n-heptyl-N′-4-aminobutylperylene-3,4,9,10-bis(dicarboximide), 2-(6-[3-Methoxyl propyl]-2-naphthyl)ethanamine. FIGS. 7-18 provide illustrations of the structures of these organic molecules, according to certain embodiments. With respect to FIGS. 7 and 8, each “R-group,” Rₓ may be any of ═H, R′, Me, Et, Pr, Ph, Bz, F, Cl, Br, I, NO₂, SO₃⁻ OR′, NR′₂, SCN, CN, N₃, SR′, where R′ may be any hydrogen, alkyl, alkenyl, or alkynyl chain. Additionally, at least one of the illustrated Rₓ groups may be (CH₂)ₙEX_{y} or (CH₂)ₙC(EX_{y})₂ where n and y=0, 1, 2, or greater, n and y may or may not be equal, E is selected from the group consisting of C, Si, O, S, Se, Te, N, P, As, or B, and X is a halide or pseudohalide such as F, Cl, Br, I, CN, or SCN. Further, with respect to FIG. 9, the illustrated molecules may include any hydrohalide of each illustrated amine, for example benzylammonium salts, where the illustrated X group may be F, Cl, Br, I, SCN, CN, or any other pseudohalide. Other non-halide acceptable anions may include: nitrate, nitrite, carboxylate, acetate, acetonyl acetonate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tricyanomethanide, amide, and permanganate. Suitable R groups may also include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X═F, Cl, Br, or I; any aromatic group (e.g., phenyl, alkylphenl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCₓH_{y}, where x=0-20, y=1-42.

In certain embodiments, the first photoactive material may be a material with an optical band gap between approximately 1.7 eV and 1.9 eV. The first photoactive material may be an electron donor (p-type) material, and/or an electron acceptor (n-type) material, and/or an ambipolar semiconductor, which exhibits both p- and n-type material characteristics, and/or an intrinsic semiconductor which exhibits neither n-type nor p-type characteristics.

The PV cell 1000 also includes a second photoactive layer 1042. The second photoactive layer includes a second photoactive material. In certain embodiments, the second photoactive material is selected from the group consisting of perovskite, PbS, silicon, CdTe, CIGS, GaAs, InP, and Ge. In other embodiments, the second photoactive material may be selected from any one or more of perovskite (for example, FAPbI₃, FASnI₃, MASnI₃, or CsSnI₃), silicon (for example, polycrystalline silicon, single-crystalline silicon, or amorphous silicon), cadmium telluride, cadmium sulfide, cadmium selenide, copper indium gallium selenide, copper indium selenide, copper zinc tin sulfide, gallium arsenide, germanium, germanium indium phosphide, indium phosphide, lead sulfide, one or more semiconducting polymers (e.g., polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); polyphenylene vinylenes and derivatives thereof (e.g., MDMO-PPV, MEH-PPV), and combinations thereof. In some embodiments, photoactive layer 1042, IFL 1033, electrode layer 1022 and substrate 1012 may formed from a monolithic substrate material. For example, photoactive layer 1042, IFL 1033, electrode layer 1022 and substrate 1012 may be regions of a silicon substrate that have each been doped or reacted to create layers within the silicon substrate with the desired properties. In certain embodiments, the second photoactive layer 1042 may include additional layers. In certain embodiments, the second photoactive layer may be less than 200 microns thick. In certain embodiments, the second photoactive material is a patterned substrate. A patterned substrate, created by etching or texturing the second substrate layer, increases refraction and thus increases the light path length to increase the efficiency of the second photoactive layer 1042. In certain embodiments, the second photoactive material has an optical band gap of approximately 1.1 eV. The second photoactive material may be an electron donor (p-type) material, and/or an electron acceptor (n-type) material, and/or an ambipolar semiconductor, which exhibits both p- and n-type material characteristics, and/or an intrinsic semiconductor which exhibits neither n-type nor p-type characteristics.

In certain embodiments, first photoactive layer 1041 and second photoactive layer 1042 may be complete PV cells that would otherwise function independently of each other. However, when combined via a recombination layer (e.g. IFL 1032) and/or one or more shared electrodes (e.g. electrode layer 2022 of FIG. 2 or electrode layer 3022 and electrode layer 3023 of FIG. 3) in tandem, first photovoltaic layer 1041 and second photovoltaic layer 1042 may outperform their individual capacities.

Various embodiments of the present disclosure provide improved materials and/or designs in various aspects of solar cell and other devices, including among other things, active materials (including hole-transport and/or electron-transport layers), interfacial layers, and overall device design.

Interfacial Layers

The present disclosure, in some embodiments, provides advantageous materials and designs of one or more IFLs within a PV.

According to various embodiments, devices may optionally include an interfacial layer between any two other layers and/or materials, although devices need not contain any interfacial layers. For example, a photovoltaic device may contain zero, one, two, three, four, five, or more interfacial layers. An interfacial layer may include any suitable material for enhancing charge transport and/or collection between two layers or materials; it may also help prevent or reduce the likelihood of charge recombination once a charge has been transported away from one of the materials adjacent to the interfacial layer. In other embodiments, such as the interfacial layers illustrated in FIG. 19, an interfacial layer or combination of interfacial layers may promote recombination to decrease voltage losses and increase device performance. For example, in a 2-terminal photovoltaic device, such as PV 1000 of FIG. 1, the interfacial layer situated between the two photoactive layers (e.g. IFL 1032) may be configured to enhance charge recombination. IFL 1032 may include multiple layers, such as the IFLs illustrated by FIG. 19. For example, IFL 1032 may include a p-type layer 1911, an n-type layer 1912, and a thin metal layer 1913. In other embodiments, layer 1911 may be n-type and layer 1912 may be p-type. Thin metal layer 1913 may be any conductive metal (e.g. Al, Ag, Au, Cr, Cu, Pt), and may be contiguous or dis-contiguous (e.g. thin metal strips or a lattice) and is thin enough to be transparent. In other embodiments, IFL 1032 may include a p-type layer 1921, an n-type layer 1922, and a transparent conductive oxide layer 1923. Examples of transparent conductive oxide layers 1923 include ITO, FTO, doped-oxides (e.g. Ga:ZnO, Al:ZnO). In other embodiments, IFL 1032 may include a p-type layer 1931, an n-type layer 1932, and metallic nanoparticles 1933. Metallic nanoparticles 1933 may include any conductive metals, such as Ag, Au, Cu, Al, or Pt. In embodiments in which thin metal layer 1913 or transparent conductive oxide 1923 are connected to an external load, such as a three-terminal device illustrated in FIG. 2, layers 1911/1921 and 1912/1922 may both be n-type or both be p-type owing to the parallel circuit orientation of three-terminal devices.

An interfacial layer may additionally physically and electrically homogenize its substrates to create variations in substrate roughness, dielectric constant, adhesion, creation or quenching of defects (e.g., charge traps, surface states). Suitable interfacial materials may include any one or more of: Ag; Al; Au; B; Bi; Ca; Cd; Ce; Co; Cu; Fe; Ga; Ge; H; In; Mg; Mn; Mo; Nb; Ni; Pt; Sb; Sc; Si; Sn; Ta; Ti; V; W; Y; Zn; Zr; carbides of any of the foregoing metals (e.g., SiC, Fe₃C, WC, VC, MoC, NbC); silicides of any of the foregoing metals (e.g., Mg₂Si, SrSi₂, Sn₂Si); oxides of any of the foregoing metals (e.g., alumina, silica, titania, SnO₂, ZnO, NiO, ZrO₂, HfO₂), include transparent conducting oxides (“TCOs”) such as indium tin oxide, aluminum doped zinc oxide (AZO), cadmium oxide (CdO), and fluorine doped tin oxide (FTO); sulfides of any of the foregoing metals (e.g., CdS, MoS₂, SnS₂); nitrides of any of the foregoing metals (e.g., GaN, Mg₃N₂, TiN, BN, Si₃N₄); selenides of any of the foregoing metals (e.g., CdSe, FeS₂, ZnSe); tellurides of any of the foregoing metals (e.g., CdTe, TiTe₂, ZnTe); phosphides of any of the foregoing metals (e.g., InP, GaP, GaInP); arsenides of any of the foregoing metals (e.g., CoAs₃, GaAs, InGaAs, NiAs); antimonides of any of the foregoing metals (e.g., AlSb, GaSb, InSb); halides of any of the foregoing metals (e.g., CuCl, CuI, BiI₃); pseudohalides of any of the foregoing metals (e.g., CuSCN, AuCN, Fe(SCN)₂); carbonates of any of the foregoing metals (e.g., CaCO₃, Ce₂(CO₃)₃); functionalized or non-functionalized alkyl silyl groups; graphite; graphene; fullerenes; carbon nanotubes; any mesoporous material and/or interfacial material discussed elsewhere herein; and combinations thereof (including, in some embodiments, bilayers, trilayers, or multi-layers of combined materials). In some embodiments, an interfacial layer may include perovskite material. Further, interfacial layers may comprise doped embodiments of any interfacial material mentioned herein (e.g., Y-doped ZnO, N-doped single-wall carbon nanotubes). Interfacial layers may also comprise a compound having three of the above materials (e.g., CuTiO₃, Zn₂SnO₄) or a compound having four of the above materials (e.g., CoNiZnO). The materials listed above may be present in a planar, mesoporous or otherwise nano-structured form (e.g. rods, spheres, flowers, pyramids), or aerogel structure.

First, as previously noted, one or more IFLs (e.g., IFL 1030 as shown in FIG. 1) may comprise a photoactive organic compound of the present disclosure as a self-assembled monolayer (SAM) or as a thin film. When a photoactive organic compound of the present disclosure is applied as a SAM, it may comprise a binding group through which it may be covalently or otherwise bound to the surface of either or both of the anode and cathode. The binding group of some embodiments may comprise any one or more of COOH, SiX₃ (where X may be any moiety suitable for forming a ternary silicon compound, such as Si(OR)₃ and SiCl₃), SO₃, PO₄H, OH, CH₂X (where X may comprise a Group 17 halide), and O. The binding group may be covalently or otherwise bound to an electron-withdrawing moiety, an electron donor moiety, and/or a core moiety. The binding group may attach to the electrode surface in a manner so as to form a directional, organized layer of a single molecule (or, in some embodiments, multiple molecules) in thickness (e.g., where multiple photoactive organic compounds are bound to the anode and/or cathode). As noted, the SAM may attach via covalent interactions, but in some embodiments, it may attach via ionic, hydrogen-bonding, and/or dispersion force (i.e., Van Der Waals) interactions. Furthermore, in certain embodiments, upon light exposure, the SAM may enter into a zwitterionic excited state, thereby creating a highly-polarized IFL, which may direct charge carriers from an active layer into an electrode (e.g., either the anode or cathode). This enhanced charge-carrier injection may, in some embodiments, be accomplished by electronically poling the cross-section of the active layer and therefore increasing charge-carrier drift velocities towards their respective electrode (e.g., hole to anode; electrons to cathode). Molecules for anode applications of some embodiments may comprise tunable compounds that include a primary electron donor moiety bound to a core moiety, which in turn is bound to an electron-withdrawing moiety, which in turn is bound to a binding group. In cathode applications according to some embodiments, IFL molecules may comprise a tunable compound comprising an electron poor moiety bound to a core moiety, which in turn is bound to an electron donor moiety, which in turn is bound to a binding group. When a photoactive organic compound is employed as an IFL according to such embodiments, it may retain photoactive character, although in some embodiments it need not be photoactive.

Metal oxides may be used in thin film IFLs of some embodiments and may include semiconducting metal oxides, such as NiO, SnO₂, WO₃, V₂O₅, or MoO₃. The embodiment wherein the second (e.g., n-type) active material comprises TiO₂ coated with a thin-coat IFL comprising Al₂O₃ could be formed, for example, with a precursor material such as Al(NO₃)₃.xH₂O, or any other material suitable for depositing Al₂O₃ onto the TiO₂, followed by thermal annealing and dye coating. In example embodiments wherein a MoO₃ coating is instead used, the coating may be formed with a precursor material such as Na₂Mo₄.2H₂O; whereas a V₂O₅ coating according to some embodiments may be formed with a precursor material such as NaVO₃; and a WO₃ coating according to some embodiments may be formed with a precursor material such as NaWO₄.H₂O. The concentration of precursor material (e.g., Al(NO₃)₃.xH₂O) may affect the final film thickness (here, of Al₂O₃) deposited on the TiO₂ or other active material. Thus, modifying the concentration of precursor material may be a method by which the final film thickness may be controlled. For example, greater film thickness may result from greater precursor material concentration. Greater film thickness may not necessarily result in greater PCE in a PV device comprising a metal oxide coating. Thus, a method of some embodiments may include coating a TiO₂ (or other mesoporous) layer using a precursor material having a concentration in the range of approximately 0.5 to 10.0 mM; other embodiments may include coating the layer with a precursor material having a concentration in the range of approximately 2.0 to 6.0 mM; or, in other embodiments, approximately 2.5 to 5.5 mM.

Furthermore, although referred to herein as Al₂O₃ and/or alumina, it should be noted that various ratios of aluminum and oxygen may be used in forming alumina. Thus, although some embodiments discussed herein are described with reference to Al₂O₃, such description is not intended to define a required ratio of aluminum in oxygen. Rather, embodiments may include any one or more aluminum-oxide compounds, each having an aluminum oxide ratio according to AlₓO_{y}, where x may be any value, integer or non-integer, between approximately 1 and 100. In some embodiments, x may be between approximately 1 and 3 (and, again, need not be an integer). Likewise, y may be any value, integer or non-integer, between 0.1 and 100. In some embodiments, y may be between 2 and 4 (and, again, need not be an integer). In addition, various crystalline forms of AlₓO_{y} may be present in various embodiments, such as alpha, gamma, and/or amorphous forms of alumina.

Likewise, although referred to herein as NiO, MoO₃, WO₃, and V₂O₅, such compounds may instead or in addition be represented as NiₓO_{y} MoₓO_{y}, WₓO_{y}, and VₓO_{y}, respectively. Regarding each of MoₓO_{y} and WₓO_{y}, x may be any value, integer or non-integer, between approximately 0.5 and 100; in some embodiments, it may be between approximately 0.5 and 1.5. Likewise, y may be any value, integer or non-integer, between approximately 1 and 100. In some embodiments, y may be any value between approximately 1 and 4. Regarding VₓO_{y}, x may be any value, integer or non-integer, between approximately 0.5 and 100; in some embodiments, it may be between approximately 0.5 and 1.5. Likewise, y may be any value, integer or non-integer, between approximately 1 and 100; in certain embodiments, it may be an integer or non-integer value between approximately 1 and 10. In some embodiments, x and y may have values so as to be in a non-stoichiometric ratio.

In some embodiments, the IFL may comprise a titanate. A titanate according to some embodiments may be of the general formula M′TiO₃, where M′ comprises any 2+ cation. In some embodiments, M′ may comprise a cationic form of Be, Mg, Ca, Sr, Ba, Ni, Zn, Cd, Hg, Cu, Pd, Pt, Sn, or Pb. In some embodiments, the IFL may comprise a single species of titanate, which in other embodiments, the IFL may comprise two or more different species of titanates. In one embodiment, the titanate has the formula SrTiO₃. In another embodiment, the titanate may have the formula BaTiO₃. In yet another embodiment, the titanate may have the formula CaTiO₃.

By way of explanation, and without implying any limitation, titanates have a perovskite crystalline structure and strongly seed the perovskite material (e.g., MAPbI₃, FAPbI₃) growth conversion process. Titanates generally also meet other IFL requirements, such as ferroelectric behavior, sufficient charge carrier mobility, optical transparency, matched energy levels, and high dielectric constant.

In other embodiments, the IFL may comprise a zirconate. A zirconate according to some embodiments may be of the general formula M′ZrO₃, where M′ comprises any 2+ cation. In some embodiments, M′ may comprise a cationic form of Be, Mg, Ca, Sr, Ba, Ni, Zn, Cd, Hg, Cu, Pd, Pt, Sn, or Pb. In some embodiments, the IFL may comprise a single species of zirconate, which in other embodiments, the IFL may comprise two or more different species of zirconate. In one embodiment, the zirconate has the formula SrZrO₃. In another embodiment, the zirconate may have the formula BaZrO₃. In yet another embodiment, the zirconate may have the formula CaZrO₃.

By way of explanation, and without implying any limitation, zirconates have a perovskite crystalline structure and strongly seed the perovskite material (e.g., MAPbI₃, FAPbI₃) growth conversion process. Zirconates generally also meet other IFL requirements, such as ferroelectric behavior, sufficient charge carrier mobility, optical transparency, matched energy levels, and high dielectric constant.

In other embodiments, the IFL may comprise a stannate. A stannate according to some embodiments may be of the general formula M′ SnO₃, or M′₂SnO₄ where M′ comprises any 2+ cation. In some embodiments, M′ may comprise a cationic form of Be, Mg, Ca, Sr, Ba, Ni, Zn, Cd, Hg, Cu, Pd, Pt, Sn, or Pb. In some embodiments, the IFL may comprise a single species of stannate, which in other embodiments, the IFL may comprise two or more different species of stannate. In one embodiment, the stannate has the formula SrSnO₃. In another embodiment, the stannate may have the formula BaSnO₃. In yet another embodiment, the stannate may have the formula CaSnO₃.

By way of explanation, and without implying any limitation, stannates have a perovskite crystalline structure and strongly seed the perovskite material (e.g., MAPbI₃, FAPbI₃) growth conversion process. Stannates generally also meet other IFL requirements, such as ferroelectric behavior, sufficient charge carrier mobility, optical transparency, matched energy levels, and high dielectric constant.

In other embodiments, the IFL may comprise a plumbate. A plumbate according to some embodiments may be of the general formula M′PbO₃, where M′ comprises any 2+ cation. In some embodiments, M′ may comprise a cationic form of Be, Mg, Ca, Sr, Ba, Ni, Zn, Cd, Hg, Cu, Pd, Pt, Sn, or Pb. In some embodiments, the IFL may comprise a single species of plumbate, which in other embodiments, the IFL may comprise two or more different species of plumbate. In one embodiment, the plumbate has the formula SrPbO₃. In another embodiment, the plumbate may have the formula BaPbO₃. In yet another embodiment, the plumbate may have the formula CaPbO₃. In yet another embodiment, the plumbate may have the formula Pb^{II}Pb^{IV}O₃.

By way of explanation, and without implying any limitation, plumbates have a perovskite crystalline structure and strongly seed the perovskite material (e.g., MAPbI₃, FAPbI₃) growth conversion process. Plumbates generally also meet other IFL requirements, such as ferroelectric behavior, sufficient charge carrier mobility, optical transparency, matched energy levels, and high dielectric constant.

Further, in other embodiments, an IFL may comprise a combination of a zirconate and a titanate in the general formula M′[ZrₓTi₁₋ₓ]O₃, where x is greater than 0 but less than one 1, and M′ comprises any 2+ cation. In some embodiments, M′ may comprise a cationic form of Be, Mg, Ca, Sr, Ba, Ni, Zn, Cd, Hg, Cu, Pd, Pt, Sn, or Pb. In some embodiments, the IFL may comprise a single species of zirconate, which in other embodiments, the IFL may comprise two or more different species of zirconate. In one embodiment, the zirconate/titanate combination has the formula Pb[ZrₓTi₁₋ₓ]O₃. In another embodiment, the zirconate/titanate combination has the formula Pb[Zr_{0.52}Ti_{0.48}]O₃.

By way of explanation, and without implying any limitation, a zirconate/titanate combination have a perovskite crystalline structure and strongly seed the perovskite material (e.g., MAPbI₃, FAPbI₃) growth conversion process. Zirconate/titanate combinations generally also meet other IFL requirements, such as ferroelectric behavior, sufficient charge carrier mobility, optical transparency, matched energy levels, and high dielectric constant.

In other embodiments, the IFL may comprise a niobate. A niobate according to some embodiments may be of the general formula M′NbO₃, where: M′ comprises any 1+ cation. In some embodiments, M′ may comprise a cationic form of Li, Na, K, Rb, Cs, Cu, Ag, Au, Tl, ammonium, or H. In some embodiments, the IFL may comprise a single species of niobate, which in other embodiments, the IFL may comprise two or more different species of niobate. In one embodiment, the niobate has the formula LiNbO₃. In another embodiment, the niobate may have the formula NaNbO₃. In yet another embodiment, the niobate may have the formula AgNbO₃.

By way of explanation, and without implying any limitation, niobates generally meet IFL requirements, such as piezoelectric behavior, non-linear optical polarizability, photoelasticity, ferroelectric behavior, Pockels effect, sufficient charge carrier mobility, optical transparency, matched energy levels, and high dielectric constant.

Any interfacial material discussed herein may further comprise doped compositions. To modify the characteristics (e.g., electrical, optical, mechanical) of an interfacial material, a stoichiometric or non-stoichiometric material may be doped with one or more elements (e.g., Na, Y, Mg, N, P) in amounts ranging from as little as 1 ppb to 50 mol %. Some examples of interfacial materials include: NiO, TiO₂, SrTiO₃, Al₂O₃, ZrO₂, WO₃, V₂O₅, MO₃, ZnO, graphene, and carbon black. Examples of possible dopants for these interfacial materials include: Li, Na, Be, Mg, Ca, Sr, Ba, Sc, Y, Nb, Ti, Fe, Co, Ni, Cu, Ga, Sn, In, B, N, P, C, S, As, a halide, a pseudohalide (e.g., cyanide, cyanate, isocyanate, fulminate, thiocyanate, isothiocyanate, azide, tetracarbonylcobaltate, carbamoyldicyanomethanide, dicyanonitrosomethanide, dicyanamide, and tricyanomethanide), and Al in any of its oxidation states. References herein to doped interfacial materials are not intended to limit the ratios of component elements in interfacial material compounds.

In some embodiments, multiple IFLs made from different materials may be arranged adjacent to each other to form a composite IFL. This configuration may involve two different IFLs, three different IFLs, or an even greater number of different IFLs. The resulting multi-layer IFL or composite IFL may be used in lieu of a single-material IFL. For example, a composite IFL may be used any IFL shown in the example of FIG. 2, such as IFL 3903, IFL 3905, IFL 3907, IFL 3909, or IFL 3911. While the composite IFL differs from a single-material IFL, the assembly of a perovskite material PV cell having multi-layer IFLs is not substantially different than the assembly of a perovskite material PV cell having only single-material IFLs.

Generally, the composite IFL may be made using any of the materials discussed herein as suitable for an IFL. In one embodiment, the IFL comprises a layer of Al₂O₃ and a layer of ZnO or M:ZnO (doped ZnO, e.g., Be:ZnO, Mg:ZnO, Ca:ZnO, Sr:ZnO, Ba:ZnO, Sc:ZnO, Y:ZnO, Nb:ZnO). In an embodiment, the IFL comprises a layer of ZrO₂ and a layer of ZnO or M:ZnO. In certain embodiments, the IFL comprises multiple layers. In some embodiments, a multi-layer IFL generally has a conductor layer, a dielectric layer, and a semi-conductor layer. In particular embodiments the layers may repeat, for example, a conductor layer, a dielectric layer, a semi-conductor layer, a dielectric layer, and a semi-conductor layer. Examples of multi-layer IFLs include an IFL having an ITO layer, an Al₂O₃ layer, a ZnO layer, and a second Al₂O₃ layer; an IFL having an ITO layer, an Al₂O₃ layer, a ZnO layer, a second Al₂O₃ layer, and a second ZnO layer; an IFL having an ITO layer, an Al₂O₃ layer, a ZnO layer, a second Al₂O₃ layer, a second ZnO layer, and a third Al₂O₃ layer; and IFLs having as many layers as necessary to achieve the desired performance characteristics. As discussed previously, references to certain stoichiometric ratios are not intended to limit the ratios of component elements in IFL layers according to various embodiments.

Arranging two or more adjacent IFLs as a composite IFL may outperform a single IFL in perovskite material PV cells where attributes from each IFL material may be leveraged in a single IFL. For example, in the architecture having an ITO layer, an Al₂O₃ layer, and a ZnO layer, where ITO is a conducting electrode, Al₂O₃ is a dielectric material and ZnO is a n-type semiconductor, ZnO acts as an electron acceptor with well performing electron transport properties (e.g., mobility). Additionally, Al₂O₃ is a physically robust material that adheres well to ITO, homogenizes the surface by capping surface defects (e.g., charge traps), and improves device diode characteristics through suppression of reverse saturation current.

As discussed above, each illustrated IFLs may include multiple layers. For example, in a 2-terminal tandem solar cell device as illustrated in FIG. 1, IFL 1032 may include the following layers, listed in order from either top to bottom or bottom to top: electron transport layer, recombination layer, hole transport layer.

In certain embodiments, an IFL may comprise an internal electrode that is connected to an external load. In other embodiments, particularly in a 3-terminal design, an IFL may comprise an internal electrode embedded in IFL 2030 that is connected to an external load. In other embodiments, an IFL must be transparent to light having a wavelength greater than 500 nanometers.

Perovskite Material

As described above, a perovskite material may be incorporated into various of one or more aspects of a PV or other device. A perovskite material according to some embodiments may be of the general formula C_{w}M_{y}X_{z}, where C comprises one or more cations (e.g., an amine, ammonium, phosphonium, a Group 1 metal, a Group 2 metal, and/or other cations or cation-like compounds); M is one or more metals (examples including Be, Mg, Ca, Sr, Ba, Fe, Cd, Co, Ni, Cu, Ag, Au, Hg, Sn, Ge, Ga, Pb, In, Tl, Sb, Bi, Ti, Zn, Cd, Hg, and Zr); X is one or more anions selected from the group consisting of oxides, halides, pseudohalides, chalcogenides (tellurides, sulfides, and selenides), and combinations thereof; and w, y, and z represent real numbers between 1 and 20. In some embodiments, C may include one or more organic cations. In some embodiments, each organic cation C may be larger than each metal M, and each anion X may be capable of bonding with both a cation C and a metal M. In particular embodiments, a perovskite material may be of the formula CMX₃.

The inclusion of bulky organic cations, near or at the surface of a perovskite material may result in the formula of the perovskite material deviating from the “ideal” stoichiometry of perovskite materials disclosed herein. For example, inclusion of such organic cations may cause the perovskite material to have a formula that is either substoichiometric or superstoichiometric with respect to the CMX₃ formula described herein. In this case, the general formula for the perovskite material may be expressed as C_{w}M_{y}X_{z}, where w, y and z are real numbers. In some embodiments, a perovskite material may have the formula C′₂Cₙ₋₁MₙX₃ₙ₋₁, where n is an integer. For example, when n=1 the perovskite material may have the formula C′₂MX₄, when n=2 the perovskite material may have the formula C′₂CM₂X₇, when n=3 the perovskite material may have the formula C′₂C₂M₃X₁₀, when n=4 the perovskite material may have the formula C′₂C₃M₄X₁₃, and so on. As illustrated by FIG. 5, the n-value indicates the thickness of an inorganic metal halide sublattice of the perovskite material. A phase of the perovskite material having the formula C′₂Cₙ₋₁MₙX₃ₙ₋₁, may form in regions where a bulky organic cation has diffused into, or otherwise entered into, the crystal lattice of a perovskite material. A 2-D perovskite material according to some embodiments may be of the general formula (C′)ₐ(C)_{b}MₙX₃ₙ₊₁, wherein C′ is a bulky organic cation, C is a small organic or inorganic cation, M is a divalent metal or combination of monovalent and trivalent metals and may be written in the form M′M″ where M′ is a monovalent metal and M″ is a trivalent metal, X is a halide, and a, b are real numbers and n is an integer. In embodiments in which M includes both a monovalent and trivalent metal, the ratio of monovalent metal to trivalent metal may range from 1:99 to 50:50, and in particular embodiments may be 1:99, 25:75; or 50:50. As illustrated in FIG. 5, the n value indicates the thickness of an inorganic metal halide sublattice comprising at least one of Pb, I, N, C, and H. FIG. 6 to FIG. 18 provide chemical structures of organic compounds that may be included in the perovskite material as C′ or C cations. C′, C, M, X, and the n value may be selected to achieve an optical band gap of 1.70-1.90 eV for the top cell (i.e. the photoactive layer nearest the sun) as well as improving the long-term stability of, for example, Si/perovskite tandem solar cells. The bandgap may be tailored for the properties of the bottom cell, in cases such as CdTe/perovskite, CIGS/perovskite, GaAs/perovskite, InP/perovskite, Ge/perovskite, amongst others. In certain embodiments, n is a value between 1 and 10, and in particular embodiments between 3 and 4, X is iodide, M is lead, C is cesium, methylammonium or formamidinium, and C′ is one of benzylammonium, phenylethylammonium, n-butylammonium, iminomethanediammonium, a cation of 4-(aminomethyl)piperidine.

In certain embodiments, C′ is benzylammonium and C is cesium, methylammonium or formamidinium. In other embodiments, C′ is phenylethylammonium and C is cesium, methylammonium or formamidinium. In certain embodiments, C′ is n-butylammonium and C is cesium, methylammonium or formamidinium. In other embodiments, C′ is iminomethanediammonium and C is cesium, methylammonium or formamidinium. In certain embodiments, C′ is a cation of 4-(aminomethyl)piperidine and C is cesium, methylammonium or formamidinium.

Examples of other “bulky organic” organic cations that may function as C′, include, but are not limited to, ethylammonium, propylammonium, n-butylammonium; perylene n-butylamine-imide; butane-1,4-diammonium; 1-pentylammonium; 1-hexylammonium; poly(vinylammonium); phenylethylammonium; 3-phenyl-1-propylammonium; 4-phenyl-1-butylammonium; 1,3-dimethylbutylammonium; 3,3-dimethylbutylammonium; 1-heptylammonium; 1-octylammonium; 1-nonylammonium; 1-decylammonium; and 1-icosanyl ammonium. Additionally, bulky organic cations with a tail that contains one or more heteroatoms in addition to the cationic species, the heteroatom may coordinate with, bind to, or integrate with the perovskite material crystal lattice. A heteroatom may be any atom in the tail that is not hydrogen or carbon, including boron, nitrogen, sulfur, oxygen, or phosphorous.

Other examples of bulky organic cations may include the following molecules functionalized with an ammonium group, phosphonium group, or other cationic group that may integrate into a surface C-site of a perovskite material: benzene, pyridine, naphthalene, anthracene, xanthene, phenathrene, tetracene chrysene, tetraphene, benzo[c]phenathrene, triphenylene, pyrene, perylene, corannulene, coronene, substituted dicarboxylic imides, aniline, N-(2-aminoethyl)-2-isoindole-1,3-dione, 2-(1-aminoethyl)naphthalene, 2-triphenylene-O-ethyl amine ether, benzylamine, benzylammonium salts, N-n-butyl-N′-4-aminobutylperylene-3,4,9,10-bis(dicarboximide), 1-(4-alkylphenyl)methanamine, 1-(4-alkyl-2-phenyl)ethanamine, 1-(4-alkylphenyl)methanamine, 1-(3-alkyl-5-alkylphenyl)methanamine, 1-(3-alkyl-5-alkyl-2-phenyl)ethanamine, 1-(4-alkyl-2-phenyl)ethanamine, 2-Ethylamine-7-alkyl-Naphthalene, 2-Ethylamine-6-alkyl-Naphthalene, 1-Ethylamine-7-alkyl-Naphthalene, 1-Ethylamine-6-alkyl-Naphthalene, 2-Methylamine-7-alkyl-Naphthalene, 2-Methylamine-6-alkyl-Naphthalene, 1-Methylamine-7-alkyl-Naphthalene, 1-Methylamine-6-alkyl-Naphthalene, N-n-aminoalkyl-N′-4-aminobutylperylene-3,4,9,10-bis(dicarboximide), 1-(3-Butyl-5-methoxybutylphenyl)methanamine, 1-(4-Pentylphenyl)methanamine, 1-[4-(2-Methylpentyl)-2-phenyl]ethanamine, 1-(3-Butyl-5-pentyl-2-phenyl)ethanamine, 2-(5-[4-Methylpentyl]-2-naphthyl)ethanamine, N-7-tridecyl-N′-4-aminobutylperylene-3,4,9,10-bis(dicarboximide), N-n-heptyl-N′-4-aminobutylperylene-3,4,9,10-bis(dicarboximide), 2-(6-[3-Methoxyl propyl]-2-naphthyl)ethanamine. FIGS. 6-18 provide illustrations of the structures of these organic molecules, according to certain embodiments. With respect to FIGS. 7 and 8, each “R-group,” Rₓ may be any of ═H, R′, Me, Et, Pr, Ph, Bz, F, Cl, Br, I, NO₂, OR′, NR′₂, SCN, CN, N₃, SR′, where R′ may be any alkyl, alkenyl, or alkynyl chain. Additionally, at least one of the illustrated Rₓ groups may be (CH₂)ₙEX_{y} or (CH₂)ₙC(EX_{y})₂ where n and y=0, 1, 2, or greater, n and y may or may not be equal, E is selected from the group consisting of C, Si, O, S, Se, Te, N, P, As, or B, and X is a halide or pseudohalide such as F, Cl, Br, I, CN, or SCN. Further, with respect to FIG. 9, the illustrated molecules may include any hydrohalide of each illustrated amine, for example benzylammonium salts, where the illustrated X group may be F, Cl, Br, I, SCN, CN, or any other pseudohalide. Other non-halide acceptable anions may include: nitrate, nitrite, carboxylate, acetate, acetonyl acetonate, formate, oxalate, sulfate, sulfite, thiosulfate, phosphate, tetrafluoroborate, hexafluorophosphate, tetra(perfluorophenyl) borate, hydride, oxide, peroxide, hydroxide, nitride, arsenate, arsenite, perchlorate, carbonate, bicarbonate, chromate, dichromate, iodate, bromate, chlorate, chlorite, hypochlorite, hypobromite, cyanide, cyanate, isocyanate, fulminate, thiocyanate, isothiocyanate, azide, tetracarbonylcobaltate, carbamoyldicyanomethanide, dicyanonitrosomethanide, dicyanamide, tricyanomethanide, amide, and permanganate. Suitable R groups may also include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X═F, Cl, Br, or I; any aromatic group (e.g., phenyl, alkylphenl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCₓH_{y}, where x=0-20, y=1-42.

Two-dimensional lead iodide perovskite materials described in some embodiments of this disclosure only substantially contain one type of anioniodide. Thus, the 2D lead iodide perovskite materials of some embodiments of the present disclosure will not undergo halide phase segregation upon sunlight irradiation, unlike the mixture of iodide and bromide currently used in the state-of-the-art Si/perovskite and perovskite/perovskite tandem solar cells.

2D Perovskite Tandem Photovoltaic Device Design

2D perovskite materials disclosed herein may function well as a photoactive layer in tandem photovoltaic devices having a silicon photoactive layer. For example, with reference to FIGS. 1, 2, and 3, such photoactive devices may include a silicon photoactive layer (e.g. photoactive layers 1042, 2042, or 3042) and a 2D perovskite photoactive layer (e.g. photoactive layers 1041, 2041, or 3041). In the illustrated embodiments, the larger band gap photoactive material (i.e. the 2D perovskite photoactive material) is disposed on the light incident side of the PV cell and the smaller bandgap material (i.e. silicon) is disposed behind the larger band gap photovoltaic material with respect to the path length of the incident light. In certain embodiments, one or more layers illustrated in FIG. 1, 2, or 3 maybe omitted from such a silicon/2D perovskite material device. Further, as explained previously in this disclosure, any illustrated IFL may include multiple layers of IFLs. Examples of desirable 2D perovskite materials for inclusion in silicon tandem device are listed below in Tables 1 and 2. In particular embodiments, a tandem PV cell may include a 2D perovskite material photoactive layer and a CdTe photoactive layer. For example, with reference to FIGS. 1, 2, and 3, such photoactive devices may include a CdTe photoactive layer (e.g. photoactive layers 1042, 2042, or 3042) and a 2D perovskite photoactive layer (e.g. photoactive layers 1041, 2041, or 3041). In other embodiments, a tandem PV cell may include two perovskite layers, wherein, as described above, the larger band gap perovskite material layer is disposed closer to the light incident side of the PV cell than the lower band gap perovskite material. For example, with reference to Tables 1 and 2 below, a perovskite material with the formula (C′)₂(C)₃Pb₄I₁₃ where C′ is n-butylamine and C is methylamine may be the “top” (closest to the sun) photoactive layer and a perovskite material with the formula FASnI₃ may be the “bottom” (farther from the sun) photoactive layer.

TABLE 1

| | | | E_{g} | PL |
|---|---|---|---|---|
| Formula | C′ cation | C cation | (eV) | (eV) |
| (C′)₂(C)₃Pb₄I₁₃ | Benzylamine = C₆H₅CH₂NH₂ | Methylamine = CH₃NH₂ or | unknown | unknown |
| | | Formamidine = | | |
| | | HC(NH)NH₂ | | |
| (C′)₂(C)₃Pb₄I₁₃ | Phenylethylamine = | Methylamine = CH₃NH₂ or | unknown | unknown |
| | C₆H₅(CH₂)₂NH₂ | Formamidine = | | |
| | | HC(NH)NH₂ | | |
| (C′)₂(C)₃Pb₄I₁₃ | n-butylamine = n-C₄H₉NH₂ | Methylamine = CH₃NH₂ | 1.91 | 1.90 |
| (C′)₂(C)₃Pb₄I₁₃ | n-butylamine = n-C₄H₉NH₂ | Formamidine = | unknown | unknown |
| | | HC(NH)NH₂ | | |
| (C′)(C)₃Pb₃I₁₀ | Guanidine = C(NH₂)₂NH | Methylamine = CH₃NH₂ | 1.73 | unknown |
| (C′)(C)₃Pb₃I₁₀ | Guanidine = C(NH₂)₂NH | Formamidine = | unknown | unknown |
| | | HC(NH)NH₂ | | |
| (C′)(C′)₃Pb₄I₁₃ | 4-(aminomethyl)piperidine = | Methylamine = CH₃NH₂ | 1.89 | 1.88 |
| | 4-C₆N₂H₁₆ | | | |
| (C′)(C′)₃Pb₄I₁₃ | 4-(aminomethyl)piperidine = | Formamidine = | unknown | unknown |
| | 4-C₆N₂H₁₆ | HC(NH)NH₂ | | |

TABLE 2

| | | | E_{g} | PL |
|---|---|---|---|---|
| Formula | C′ cation | C cation | (eV) | (eV) |
| (n-C₄H₉NH₃)₂(CH₃NH₃)₂Pb₃I₁₀ | n-butylamine = n-C₄H₉NH₂ | Methylamine = | 2.03 | 2.01 |
| | | CH₃NH₂ | | |
| (n-C₄H₉NH₃)₂(CH₃NH₃)₂Pb₄I₁₃ | n-butylamine = n-C₄H₉NH₂ | Methylamine = | 1.91 | 1.90 |
| | | CH₃NH₂ | | |
| (NH₃CₘH₂ₘNH₃)(CH₃NH₃)₂Pb₃I₁₀ | Alkyldiamine = NH₃CₘH₂ₘNH₃ | Methylamine = | 2.00 | 1.96 |
| (m = 4, 6, 7, 8, 9) | | CH₃NH₂ | | |
| (NH₃CₘH₂ₘNH₃)(CH₃NH₃)₃Pb₄I₁₃ | Alkyldiamine = NH₃CₘH₂ₘNH₃ | Methylamine = | 1.90 | 1.89 |
| (m = 8, 9) | | CH₃NH₂ | | |
| (C(NH₂)₃)(CH₃NH₃)₂Pb₂I₇ | Guanidine = C(NH₂)₂NH | Methylamine = | 1.99 | unknown |
| | | CH₃NH₂ | | |
| (C(NH₂)₃)(CH₃NH₃)₃Pb₃I₁₀ | Guanidine = C(NH₂)₂NH | Methylamine = | 1.73 | unknown |
| | | CH₃NH₂ | | |
| (3-C₆N₂H₁₆)(MA)₂Pb₃I₁₀ | 3-(aminomethyl)piperidine = | Methylamine = | 1.92 | 1.90 |
| | 3-C₆N₂H₁₆ | CH₃NH₂ | | |
| (3-C₆N₂H₁₆)(MA)₃Pb₄I₁₃ | 3-(aminomethyl)piperidine = | Methylamine = | 1.87 | 1.84 |
| | 3-C₆N₂H₁₆ | CH₃NH₂ | | |
| (4-C₆N₂H₁₆)(MA)₂Pb₃I₁₀ | 4-(aminomethyl)piperidine = | Methylamine = | 1.99 | 1.97 |
| | 4-C₆N₂H₁₆ | CH₃NH₂ | | |
| (4-C₆N₂H₁₆)(MA)₃Pb₄I₁₃ | 4-(aminomethyl)piperidine = | Methylamine = | 1.89 | 1.88 |
| | 4-C₆N₂H₁₆ | CH₃NH₂ | | |
| (C₅N₃H₁₁)PbI₄ | Histamine = C₅N₃H₁₀ | Methylamine = | 2.05 | unknown |
| | | CH₃NH₂ | | |
| (C₆H₅(CH₂)₂NH₃)₂(CH₃NH₃)₂Pb₃I₁₀ | Phenyl ethylamine = | Methylamine = | 2.06 | unknown |
| | C₆H₅(CH₂)₂NH₂ | CH₃NH₂ | | |
| (C₇H₇N₂)₂PbI₄ | Benzimidazole = C₇H₆N₂ | None | 1.99 | unknown |

The perovskite materials illustrated in Tables 1 and 2 have properties, such as desirable band gaps, that allow them to function optimally in tandem photovoltaic cells with a silicon layer. Additionally, 2-D perovskites may be implemented in photovoltaic devices having three or more photoactive layers. For example, with respect to FIG. 21, photoactive layer 2141 may be a 2D perovskite, and photoactive layer layers 2142 and 2143 may be photoactive materials with narrower band gaps as described herein. For example, photoactive layer 2141 may include a 2D perovskite material, photoactive layer 2142 may include a perovskite material, and photoactive layer 2143 may include lead sulfide (PbS). In another embodiment, photoactive layer 2141 includes a 2D perovskite material, photoactive layer 2142 includes gallium arsenide (GaAs), and photoactive layer 2143 includes germanium (Ge). In yet another embodiment, photoactive layer 2141 includes a 2D perovskite material, photoactive layer 2142 includes a perovskite material, and photoactive layer 2143 includes silicon. In yet another embodiment, photoactive layer 2141 includes a 2D perovskite material, photoactive layer 2142 includes a 2D perovskite material with a narrower bandgap than the 2D perovskite material of photoactive layer 2141, and photoactive layer 2143 includes silicon.

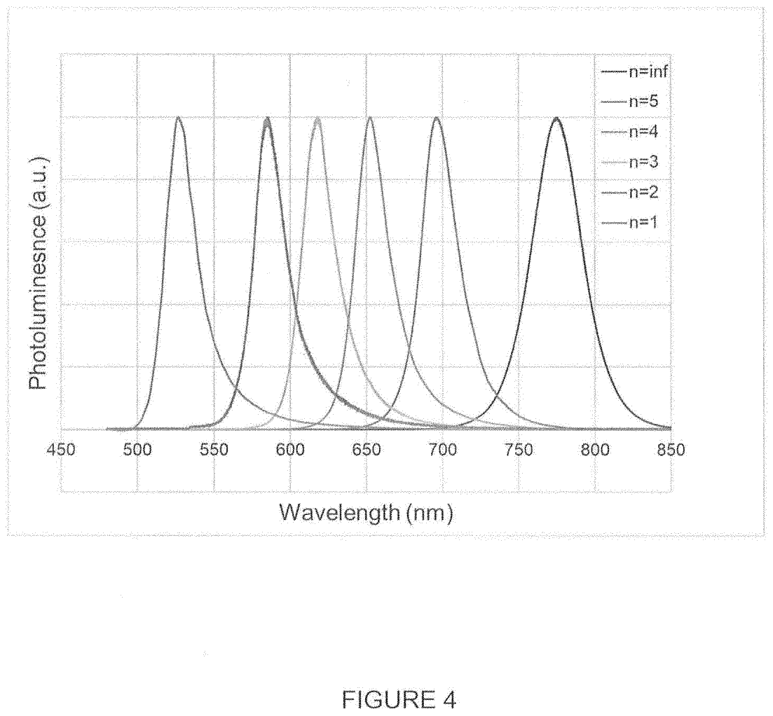

FIG. 20 presents a stylized diagram of a 2D perovskite material and silicon 2-terminal tandem PV cell. In the embodiment illustrated in FIG. 20, PV cell 1550 is a silicon PV cell. 2D perovskite material layer 1521 may be any 2D perovskite material chosen from those identified herein. IFLs 1531 and 1532 may be any IFL disclosed herein, electrode layer 1521 may be any electrode material disclosed herein, and substrate 1511 may be any substrate material disclosed herein. In particular embodiments, IFL 1532 may be a multilayer recombination layer, such as IFL 1910, IFL 1920, or IFL 1930 illustrated in FIG. 19. Further, as discussed above, a 2D perovskite material/silicon tandem PV cell may be implemented as 3-terminal or 4-terminal cell, such as those illustrated in FIG. 3 or 4.

Additionally, the 2D perovskites identified in Tables 1 and 2, and elsewhere herein, may perform well in tandem devices having a non-silicon bottom PV cell. For example, silicon PV cell 1550 may alternatively be a perovskite, CdTe, CIGS, GaAs, InP, or Ge cell. In some embodiments PV cell 1550 may alternatively include any one or more of perovskite (for example, FAPbI₃, FASnI₃, MASnI₃, or CsSnI₃), silicon (for example, polycrystalline silicon, single-crystalline silicon, or amorphous silicon), cadmium telluride, cadmium sulfide, cadmium selenide, copper indium gallium selenide, copper indium selenide, copper zinc tin sulfide, gallium arsenide, germanium, germanium indium phosphide, indium phosphide, lead sulfide, one or more semiconducting polymers (e.g., polythiophenes (e.g., poly(3-hexylthiophene) and derivatives thereof, or P3HT); carbazole-based copolymers such as polyheptadecanylcarbazole dithienylbenzothiadiazole and derivatives thereof (e.g., PCDTBT); other copolymers such as polycyclopentadithiophene-benzothiadiazole and derivatives thereof (e.g., PCPDTBT), polybenzodithiophenyl-thienothiophenediyl and derivatives thereof (e.g., PTB6, PTB7, PTB7-th, PCE-10); poly(triaryl amine) compounds and derivatives thereof (e.g., PTAA); polyphenylene vinylenes and derivatives thereof (e.g., MDMO-PPV, MEH-PPV), and combinations thereof.

In some embodiments, the present disclosure may provide composite design of PV and other similar devices (e.g., batteries, hybrid PV batteries, FETs, LEDs, nonlinear optics (NLOs), waveguides, etc.) including one or more perovskite materials. In more general terms, some embodiments of the present disclosure provide PV or other devices having an active layer comprising one or more perovskite materials. In such embodiments, perovskite material (that is, material including any one or more perovskite materials(s)) may be employed in active layers of various architectures. In some embodiments, the same perovskite materials may serve multiple such functions, although in other embodiments, a plurality of perovskite materials may be included in a device, each perovskite material serving one or more such functions. In certain embodiments, whatever role a perovskite material may serve, it may be prepared and/or present in a device in various states. For example, it may be substantially solid in some embodiments. A solution or suspension may be coated or otherwise deposited within a device (e.g., on another component of the device such as a mesoporous, interfacial, charge transport, photoactive, or other layer, and/or on an electrode). Perovskite materials in some embodiments may be formed in situ on a surface of another component of a device (e.g., by vapor deposition as a thin-film solid). Any other suitable means of forming a layer comprising perovskite material may be employed.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. In particular, every range of values (of the form, “from about a to about b,” or, equivalently, “from approximately a to b,” or, equivalently, “from approximately a-b”) disclosed herein is to be understood as referring to the power set (the set of all subsets) of the respective range of values, and set forth every range encompassed within the broader range of values. Also, the terms in the claims have their plain, ordinary meaning unless otherwise explicitly and clearly defined by the patentee.

What is claimed is:

1. A photovoltaic device comprising:
a first electrode;
a first photoactive material layer;
one or more interfacial layers;
a second photoactive material layer comprising a 2-D perovskite material having the formula (C′)ₐ(C)_{b}MₙX₃ₙ₊₁, wherein C′ is a bulky organic cation, C is a small organic or inorganic cation, M is a metal, X is a halide, a and b are real numbers, and n is an integer; and
a second electrode.

2. The photovoltaic device of claim 1, wherein:
the first photoactive material layer is positioned between the first electrode and the interfacial layer;
the interfacial layer is positioned between the first photoactive material layer and the second photoactive material layer; and
the second photoactive material layer is positioned between the interfacial layer and the second electrode.

3. The photovoltaic device of claim 1, wherein the first photoactive material layer is selected from the group consisting of FAPbI3, FASnI3, MASnI3, CsSnI3, cadmium telluride, cadmium sulfide, cadmium selenide, copper indium gallium selenide, copper indium selenide, copper zinc tin sulfide, gallium arsenide, germanium, germanium indium phosphide, indium phosphide, lead sulfide, semiconducting polymers, polythiophenes, poly(3-hexylthiophene) (P3HT), polyheptadecanylcarbazole, dithienylbenzothiadiazole, Poly[[9-(1-octylnonyl)-9H-carb azole-2,7-diyl]-2,5-thiophenediyl-2,1,3-benzothiadiazole-4,7-diyl-2,5-thiophenediyl] (PCDTBT), polycyclopentadithiophene-benzothiadiazole, poly[2,6-(4,4-bis-(2-ethylhexyl)-4H-cyclopenta [2,1-b;3,4-b′]dithiophene)-alt-4,7(2,1,3-benzothiadiazole)] (PCPDTBT), polybenzodithiophenyl-thienothiophenediyl, poly(triaryl amine) compounds, polyphenylene vinylenes, and combinations thereof.

4. The photovoltaic device of claim 1, wherein C′ is benzylammonium and C is cesium, methylammonium or formamidinium.

5. The photovoltaic device of claim 1, wherein C′ is phenylethylammonium and C is cesium, methylammonium or formamidinium.

6. The photovoltaic device of claim 1, wherein C′ is n-butylammonium and C is cesium, methylammonium or formamidinium.

7. The photovoltaic device of claim 1, wherein C′ is iminomethanediammonium and C is cesium, methylammonium or formamidinium.

8. The photovoltaic device of claim 1, wherein C′ is a cation of 4-(aminomethyl)piperidine and C is cesium, methylammonium or formamidinium.

9. The photovoltaic device of claim 1, wherein the first photoactive material layer comprises a material less than or equal to 200 microns thick.

10. The photovoltaic device of claim 1, wherein the first photoactive material layer comprises a material that is a patterned substrate.

11. The photovoltaic device of claim 1, wherein the first photoactive material layer comprises a material with an optical band gap of approximately 1.1 eV.

12. The photovoltaic device of claim 1, wherein the 2D perovskite material comprises repeating units of an inorganic metal halide sublattice comprising Pb, I, N, C, and H.

13. The photovoltaic device of claim 12, wherein an optical band gap value of the perovskite material decreases as the n value increases.

14. The photovoltaic device of claim 12, wherein the 2D perovskite material comprises no more than five repeating units of the inorganic halide sublattice.

15. The photovoltaic device of claim 1, wherein the second photoactive material layer comprises a material with an optical band gap between approximately 1.7 eV and 1.9 eV.

16. A photovoltaic device comprising:
a first electrode;
an interfacial layer;
a second electrode;
a first photoactive material layer selected from the group consisting of perovskite, silicon, CdTe, CIGS, GaAs, InP, PbS, and Ge;
a second photoactive material layer comprising a 2-D perovskite material having the formula (C′)ₐ(C)_{b}MₙX₃ₙ₊₁;
wherein:
C′ is a bulky organic cation, C is a small organic or inorganic cation, M is a metal, X is a halide, a and b are real numbers, and n is an integer;
the first photoactive material is positioned between the first electrode and the interfacial layer; and
the second photoactive material layer is positioned between the interfacial layer and the second electrode.

17. The photovoltaic device of claim 16, wherein C′ is benzylammonium and C is cesium, methylammonium or formamidinium.

18. The photovoltaic device of claim 16, wherein C′ is phenylethylammonium and C is cesium, methylammonium or formamidinium.

19. The photovoltaic device of claim 16, wherein C′ is n-butylammonium and C is cesium, methylammonium or formamidinium.

20. The photovoltaic device of claim 16, wherein C′ is iminomethanediammonium and C is cesium, methylammonium or formamidinium.

21. The photovoltaic device of claim 16, wherein C′ is a cation 4-(aminomethyl)piperidine and C is cesium, methylammonium or formamidinium.

22. The photovoltaic device of claim 16, wherein the first photoactive material layer comprises a material with an optical band gap of approximately 1.1 eV.

23. The photovoltaic device of claim 16, wherein the second photoactive material layer comprises a material with an optical band gap between approximately 1.7 eV and 1.9 eV.

24. The photovoltaic device of claim 16, wherein the first photoactive material layer comprises a material less than 200 microns thick.

25. The photovoltaic device of claim 16, wherein the first photoactive material layer comprises a material that is a patterned substrate.

26. (canceled)

27. The photovoltaic device of claim 16, wherein the 2D perovskite material comprises repeating units of an inorganic metal halide sublattice comprising Pb, I, N, C, and H.

28. The photovoltaic device of claim 27, wherein an optical band gap value of the perovskite material decreases as the n value increases.

29. The photovoltaic device of claim 27, wherein the 2-D perovskite material comprises no more than five repeating units of the inorganic halide sublattice.

30. (canceled)
